(19) United States
(12) Patent Application Publication
(10) Pub. No.: US 2026/0059919 A1
(43) Pub. Date: Feb. 26, 2026

(54) Display Apparatus

(71) Applicant: LG Display Co., Ltd., Seoul (KR)

(72) Inventor: Seokjun Jin, Paju-si, Gyeonggi-do (KR)

(21) Appl. No.: 19/289,594

(22) Filed: Aug. 4, 2025

(30) Foreign Application Priority Data
Aug. 23, 2024 (KR) 10-2024-0113468

(51) Int. Cl. H10H 29/80; G09G 3/32; H10H 29/41

(52) U.S. Cl. CPC H10H 29/8321; G09G 3/32; H10H 29/41; G09G 2300/0426; G09G 2320/0606; G09G 2320/0626; G09G 2330/021; G09G 2354/00

(57) ABSTRACT

A display apparatus comprises a substrate including a display area and a non-display area, a pixel driving circuit at the display area on the substrate, an insulating layer over the pixel driving circuit, a plurality of light emitting devices spaced apart from each other over the insulating layer and electrically connected to the pixel driving circuit, and a plurality of common cathode electrodes electrically connected to the plurality of light emitting devices and receiving a cathode voltage. The cathode voltage has a cathode-on voltage or a cathode-off voltage, and the cathode-off voltage is variable.

### CROSS-REFERENCE TO RELATED APPLICATION

This application claims the benefit of and priority to Republic of Korea Patent Application No. 10-2024-0113468 filed on Aug. 23, 2024, which is hereby incorporated by reference in its entirety.

### TECHNICAL FIELD

The present disclosure relates to a display apparatus.

### BACKGROUND ART

The display apparatus is applied to various electronic apparatuses such as televisions (TVs), mobile phones, laptops, and tablets.

The display apparatus includes an organic light emitting display apparatus that emit light by themselves and a liquid crystal display apparatus that require a separate light source.

Recently, a display apparatus including a light emitting device has attracted attention as a next-generation display apparatus. The light emitting device is made of an inorganic material, not an organic material. Accordingly, compared to the liquid crystal display apparatus or the organic light emitting display apparatus, the display apparatus including the light emitting device has a faster lighting speed, excellent luminous efficiency, and displays an image having high luminance.

### SUMMARY

The inventor of the present disclosure has performed extensive research and experiments to reduce power consumption of a display apparatus including a light emitting device. Based on the extensive research and experiments, the inventor of the present disclosure has invented a new display apparatus capable of reducing power consumption.

An embodiment of the present disclosure is directed to providing a display apparatus capable of reducing power consumption.

An embodiment of the present disclosure is directed to providing a display apparatus capable of improving the luminous efficiency of a light emitting device.

An embodiment of the present disclosure is directed to providing a display apparatus capable of simplifying the structure and low-power driving.

Additional features, advantages, and aspects of the present disclosure are set forth in part in the present disclosure and will also be apparent from the present disclosure or may be learned by practice of the inventive concepts provided herein. Other features, advantages, and aspects of the present disclosure may be realized and attained by the descriptions provided in the present disclosure, or derivable therefrom, and claims hereof as well as the appended drawings.

To achieve these and other advantages and embodiments of the present disclosure, as embodied and broadly described herein, in one or more embodiment, a display apparatus according to one or more embodiments of the present disclosure comprises a substrate including a display area and a non-display area, a pixel driving circuit at the display area on the substrate, an insulating layer over the pixel driving circuit, a plurality of light emitting devices spaced apart from each other over the insulating layer and electrically connected to the pixel driving circuit, and a plurality of common cathode electrodes electrically connected to the plurality of light emitting devices and receiving a cathode voltage. The cathode voltage has a cathode-on voltage or a cathode-off voltage, and the cathode-off voltage is variable.

Details of other exemplary embodiments will be included in the detailed description of the disclosure and the accompanying drawings.

According to an embodiment of the present disclosure, power consumption of the display apparatus may be reduced.

According to an embodiment of the present disclosure, instead of directly forming pixel circuits for driving the light emitting devices configured in each of the plurality of sub-pixels on a substrate, the structure of the display apparatus may be simplified, and high-efficiency driving and low-power driving may be achieved by mounting a pixel driving circuit (or pixel driving integrated circuit), in which the pixel circuits are integrated, on the substrate.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure.

FIG. 1 is an exploded perspective view illustrating a display apparatus according to an embodiment of the present disclosure.

FIG. 2 is a plan view of a display apparatus according to an embodiment of the present disclosure.

FIG. 3 is an enlarged view of the display apparatus according to an embodiment of the present disclosure.

FIG. 4 is a diagram illustrating a circuit structure according to an embodiment of the present disclosure.

FIGS. 5 to 7 are plan views of a display apparatus according to an embodiment of the present disclosure.

FIG. 8 is a cross-sectional view taken along line I-I′ illustrated in FIG. 2 according to an embodiment of the present disclosure.

FIG. 9 is a cross-sectional view of a first light emitting device according to an embodiment of the present disclosure.

FIG. 10 is a diagram illustrating brightness based on current flowing through a light emitting device according to an embodiment of the present disclosure.

FIG. 11 illustrates an external quantum efficiency of each of a red emitting device, a green emitting device, and a blue light emitting device according to an embodiment of the present disclosure.

FIG. 12 illustrates a reference voltage and a cathode voltage in a display apparatus according to an embodiment of the present disclosure.

FIG. 13 illustrates a variable circuit for the reference voltage and the cathode voltage according to an embodiment of the present disclosure.

FIG. 14 is a diagram illustrating screen brightness setting in a display apparatus according to an embodiment of the present disclosure.

FIG. 15 illustrates a pixel driving circuit and a light emitting device in a display apparatus according to an embodiment of the present disclosure.

FIG. 16 is a waveform diagram illustrating a cathode voltage applied to a plurality of second electrodes illustrated in FIG. 15 according to an embodiment of the present disclosure.

FIG. 17 is a waveform diagram illustrating a cathode voltage applied to a plurality of second electrodes illustrated in FIG. 15 according to an embodiment of the present disclosure.

FIGS. 18 to 21 are diagrams illustrating an apparatus to which a display apparatus according to embodiments of the present disclosure is applied.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and convenience.

### DETAILED DESCRIPTION

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. In a situation where “comprise”, “have”, and “include” described in the present disclosure are used, another part may be added unless “only” is used. The terms of a singular form can include plural forms unless referred to the contrary.

In construing an element, the element is construed as including an error range although there is no explicit description.

In describing a position relationship, for example, when a position relation between two parts is described as “on”, “over”, “under”, “next”, and “adjacent to” or the like, one or more other parts may be located between the two parts unless a more limiting term, such as “immediate(ly)”, “direct(ly)”, or “close(ly)” is used.

In describing a temporal relationship, when the temporal order is described as, for example, “after”, “subsequent”, “next”, “before”, or the like, a case that is not consecutive or not sequential can be included and thus one or more other events can occur therebetween, unless a more limiting term, such as “immediate(ly)” or “direct(ly)” is used.

It is understood that, although the terms “first,” “second,” or the like may be used herein to describe various elements, these elements should not be limited by these terms, for example, to any particular order, precedence, or number of elements. These terms are used only to distinguish one element from another. Therefore, the first element described below may be understood as the second element within the scope of the technical idea of the present disclosure.

In describing elements of the present disclosure, the terms “first”, “second”, “A”, “B”, “(a)”, “(b)”, or the like may be used. These terms are intended to identify the corresponding element from the other element, and these are not used to define the essence, basis, order, or number of the elements.

For the expression that an element is “connected”, “coupled”, “contact”, or “attach” to another element, the element may not only be directly connected, coupled, or contacted to another element, but also be indirectly connected, coupled, contacted, or attached to another element with one or more intervening elements interposed between the elements, unless otherwise specified.

For the expression that an element is “contacts” or “overlaps” with another element, the element can not only directly contact, overlap, or the like with another element, but also indirectly contact or overlap with another element with one or more intervening elements disposed or interposed between the elements, unless otherwise specified.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

“a first direction”, “a second direction”, “a third direction”, “X-axis direction”, “Y-axis direction”, and “Z-axis direction” should not be construed by a geometric relation only of a mutual vertical relation and may have broader directionality within the range that elements of the present disclosure may act functionally.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, example embodiments of a sound apparatus according to the present disclosure will be described in detail with reference to the accompanying drawings. For convenience of description, a scale of each of elements illustrated in the accompanying drawings differs from a real scale, and thus, is not limited to a scale illustrated in the drawings.

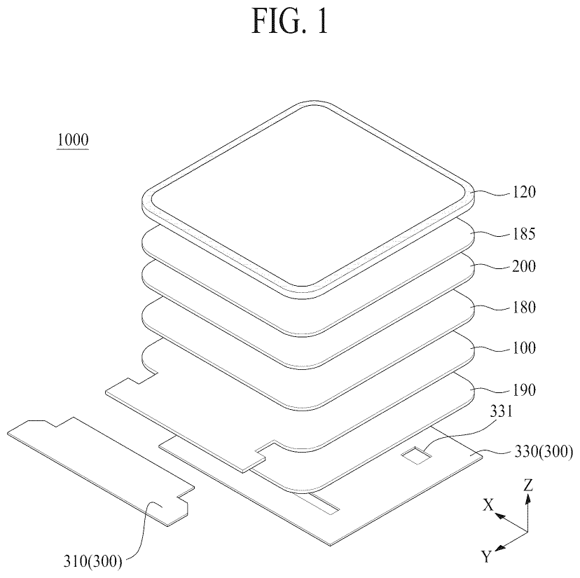

FIG. 1 is an exploded perspective view illustrating a display apparatus according to an embodiment of the present disclosure.

Referring to FIG. 1, a display apparatus 1000 according to an embodiment of the present disclosure may include a display panel 100, a cover member 120, a supporting substrate 190, and a driving circuit part 300.

The display panel 100 may be configured to implement information, images, and/or pictures provided to a user. The display panel 100 may be configured to sense a user's touch.

The cover member 120 may be disposed over the display panel 100. The cover member 120 may be a member to protect the display panel 100. The cover member 120 may be made of a transparent material. For example, the cover member 120 may be a cover window or cover glass.

The display apparatus 1000 may further include a polarizing layer 180 and an adhesive layer 185.

The polarizing layer 180 may be disposed over the display panel 100. The polarizing layer 180 may be disposed (or interposed) between the display panel 100 and the cover member 120. The polarizing layer 180 may be configured to prevent or reduce light generated from an external light source from entering an interior of the display panel 100 and affecting light emitting devices or the like.

The adhesive layer 185 may attach the cover member 120 to the display panel 100. The adhesive layer 185 may be disposed (or interposed) between the polarizing layer 180 and the cover member 120, and may attach the cover member 120 to the polarizing layer 180. The adhesive layer 185 may include an optically cleared adhesive (OCA), an optically cleared resin (OCR), or a pressure sensitive adhesive (PSA), but embodiments of the present disclosure are not limited thereto.

The supporting substrate 190 may be disposed at a rear surface of the display panel 100. The supporting substrate 190 may be configured to reinforce the rigidity of the display panel 100. For example, the supporting substrate 190 may be made of a plastic or metal material, but embodiments of the present disclosure are not limited thereto. The supporting substrate 190 may be a back plate, but embodiments of the present disclosure are not limited thereto.

A portion of the display panel 100 may be bent to surround side surfaces (or lateral surfaces) of the supporting substrate 190 and may be disposed at a rear surface of the supporting substrate 190.

The driving circuit part 300 may be electrically connected to the display panel 100. The driving circuit part 300 may be configured to generate signals required to display (or implement) an image on the display panel 100 and supply the signals to the display panel 100. The driving circuit part 300 may include a flexible printed circuit board 310 and a printed circuit board 330.

The flexible printed circuit board 310 and the printed circuit board 330 may be disposed at a lower portion of the display panel 100. The flexible printed circuit board 310 and the printed circuit board 330 may be disposed at least at an edge portion of the display panel 100, but embodiments of the present disclosure are not limited thereto. One end of the flexible printed circuit board 310 may be attached to the display panel 100, and the other end of the flexible printed circuit board 310 may be attached to the printed circuit board 330, but embodiments of the present disclosure are not limited thereto. The flexible printed circuit board 310 may be a flexible film, but embodiments of the present disclosure are not limited thereto.

The flexible printed circuit board 310 and the printed circuit board 330 may be disposed at the rear surface of the supporting substrate 190. The supporting substrate 190 may be disposed between the display panel 100 and the printed circuit board 330.

The printed circuit board 330 may include at least one hole 331, but embodiments of the present disclosure are not limited thereto. An internal component that sense ambient light or temperature, or the like, which may be provided to a plurality of sensors, may be disposed in a region corresponding to the at least one hole 331. For example, the internal component may include an ambient light sensor (ALS) or a temperature sensor, but embodiments of the present disclosure are not limited thereto. For example, the hole 331 may be a transmission hole, but embodiments of the present disclosure are not limited thereto.

The display apparatus 1000 according to an embodiment of the present disclosure may further include a touch panel 200.

The touch panel 200 may be configured to sense a user's touch on the display panel 100. For example, the touch panel 200 may sense a user's touch through a touch pen or finger. The touch panel 200 may be configured to sense screen brightness based on the user's touch.

The touch panel 200 according to one embodiment of the present disclosure may be interposed or disposed between the display panel 100 and the cover member 120. For example, the touch panel 200 may be interposed or disposed between the cover member 120 and the polarizing layer 180. The touch panel 200 may be connected or attached to a rear surface of the cover member 120 by a transparent adhesive material. The touch panel 200 may include a touch electrode layer including touch electrodes for sensing a user's finger touch or pen touch on the display panel 100. The touch electrode layer may be configured to sense a change in capacitance on the touch electrode based on the user's touch. For example, the touch electrode layer may include an electrode structure corresponding to a mutual capacitance type in which a plurality of touch driving electrodes and a plurality of touch sensing electrodes are configured to intersect, or a self-capacitance type in which only a plurality of touch sensing electrodes are configured.

The driving circuit part 300 may be electrically connected to the touch panel 200. The driving circuit part 300 may be configured to sense a change in capacitance on the touch electrodes in the touch panel 200, generate touch coordinate data corresponding to the user's touch position, and provide the touch coordinate data to a host control part.

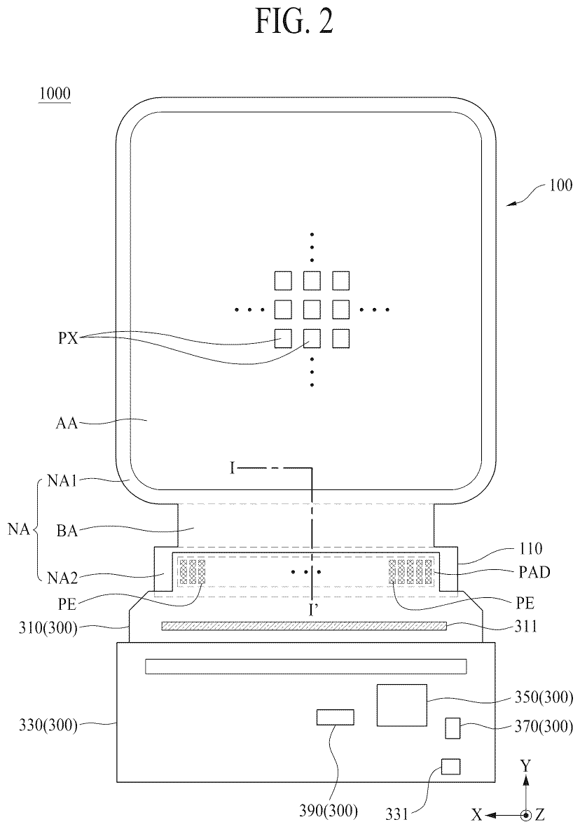

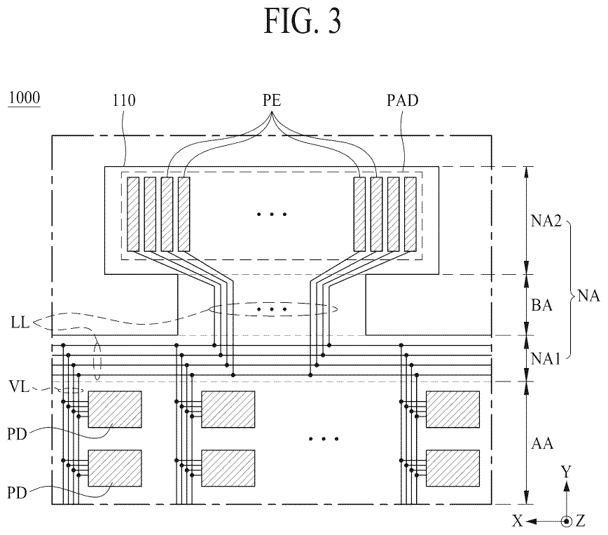

FIG. 2 is a plan view of a display apparatus according to an embodiment of the present disclosure, and FIG. 3 is an enlarged view of the display apparatus according to an embodiment of the present disclosure.

Referring to FIGS. 2 and 3, the display apparatus 1000 may include the display panel 100, a flexible printed circuit board 310, and a printed circuit board 330.

The display panel 100 may include a substrate 110. The substrate 110 may be a member configured to support the other components of the display apparatus 1000. The substrate 110 may be made of an insulating material. For example, the substrate 110 may be made of glass or resin, or the like. In addition, the substrate 110 may be made of a material having flexibility. For example, the substrate 110 may be made of a plastic material having flexibility, such as polyimide (PI) or the like, but embodiments of the present disclosure are not limited thereto.

The display panel 100 according to an embodiment of the present disclosure may include a display area AA and a non-display area NA. For example, the substrate 110 may include a display area AA and a non-display area NA. The display area AA and the non-display area NA are not limited to the substrate 110 but may be described throughout the display apparatus 1000.

The display area AA may be an area where an image is displayed. The display area AA may include a plurality of pixels PX. Each of the plurality of pixels PX may be composed of a plurality of sub-pixels. For example, each of the plurality of pixels PX may include a plurality of sub-pixels. Each of the plurality of sub-pixels may include a plurality of light emitting devices. The plurality of light emitting devices may be configured differently depending on the type of the display apparatus 1000. For example, when the display apparatus 1000 is an inorganic light emitting display apparatus, the light emitting device may be a light emitting diode (LED), a micro light emitting diode (micro LED), or a mini light emitting diode (mini LED), but embodiments of the present disclosure are not limited thereto.

The display area AA may be configured in various shapes according to a design of the display apparatus 1000. For example, the display area AA may be configured in a rectangular shape with four corners formed in a round shape, but embodiments of the present disclosure are not limited thereto. For another example, the display area AA may be configured in a rectangular shape with four corners formed in right-angled shape or a circular shape, or the like, but embodiments of the present disclosure are not limited thereto.

Referring to FIG. 3, a plurality of pixel driving circuits PD may be disposed at the display area AA. The plurality of pixel driving circuits PD may be circuits for driving the light emitting devices of the plurality of sub-pixels. Each of the plurality of pixel driving circuits PD includes a plurality of transistors including a driving transistor and a storage capacitor, or the like, and may control light emitting operations of the plurality of light emitting devices by supplying a control signal, power, and a driving current to the light emitting devices of the plurality of sub-pixels. For example, each of the plurality of pixel driving circuits PD may be electrically connected to a power wiring disposed (or configured) at the display area AA, and a signal wiring for controlling light emitting on/off and/or light emitting time of the light emitting devices. For example, each of the plurality of pixel driving circuits PD may be a microchip or a chipset and may be a semiconductor packaging device having one fine size including a plurality of transistors and a storage capacitor. For example, each of the plurality of pixel driving circuits PD may be a driving driver manufactured using a MOSFET (Metal-oxide-silicon field effect transistor) manufacturing process on a semiconductor substrate, but embodiments of the present disclosure are not limited thereto. The driving driver includes the plurality of pixel driving circuits PD and may drive the plurality of sub-pixels.

The non-display area NA may be an area surrounding the display area AA. The non-display area NA may be an area where an image is not displayed. The non-display area NA may include various wirings and driving circuits or the like for driving the plurality of pixels PX disposed (or configured) at the display area AA. For example, the various wirings and the driving circuits may be mounted at the non-display area NA, and a pad portion PAD which is connected to an integrated circuit and a printed circuit board or the like may be disposed at the non-display area NA, but embodiments of the present disclosure are not limited thereto.

According to an embodiment of the present disclosure, the driving circuit may include a driving integrated circuit 311. For example, the driving circuit may be a data driving circuit and/or a gate driving circuit, but embodiments of the present disclosure are not limited thereto. Wires to which a control signal for controlling the driving circuit is supplied may be disposed at the non-display area NA. For example, the control signal may include various timing signals including a clock signal, an input data enable signal, and synchronization signals, but embodiments of the present disclosure are not limited thereto. The control signal may be received through the pad portion PAD. For example, link lines LL for transmitting the signals may be disposed at the non-display area NA. For example, the pad portion PAD may be electrically connected to the driving circuit part 300.

According to an embodiment of the present disclosure, the non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1 and may be a bendable area. The second non-display area NA2 may be an area extending from the bending area BA and may have the pad portion PAD disposed therein. For example, the bending area BA may be in a bent state, and the remaining area of the substrate 110 excluding the bending area BA may be in a flat state. In this case, as the bending area BA is bent, the second non-display area NA2 may be located on a rear surface of the display area AA, but embodiments of the present disclosure are not limited thereto.

According to an embodiment of the present disclosure, a plurality of link lines LL may be disposed at the non-display area NA. The plurality of link lines LL may be lines that transmit various signals from one or more flexible circuit boards (or flexible films) 310 and the printed circuit boards 330 to the display area AA. The plurality of link lines LL may extend from a plurality of pad electrodes PE of the second non-display area NA2 toward the bending area BA and the first non-display area NA1, and may be electrically connected to a plurality of driving lines VL of the display area AA. The plurality of pixel driving circuits PD may be driven by receiving signals from the one or more flexible circuit boards (or flexible films) 310 and the printed circuit boards 330 through the driving lines VL of the display area AA and the link lines LL of the non-display area NA.

According to an embodiment of the present disclosure, the plurality of driving lines VL, together with the plurality of link lines LL, may be lines for transmitting signals output from the flexible circuit board (or flexible film) 310 and the printed circuit board 330 to the plurality of pixel driving circuits PD. The plurality of driving lines VL may be disposed at the display area AA and may be electrically connected to each of the plurality of pixel driving circuits PD. The plurality of driving lines VL may extend from the display area AA toward the non-display area NA and may be electrically connected to the plurality of link lines LL. Therefore, signals output from the flexible circuit board (or flexible film) 310 and the printed circuit board 330 may be transmitted to each of the plurality of pixel driving circuits PD through the plurality of link lines LL and the plurality of driving lines VL.

According to an embodiment of the present disclosure, as the bending area BA is bent, a portion of the plurality of link lines LL may be bent together. Stress is concentrated on the portion of the bent link lines LL, and thus cracks may occur in the link lines LL. Accordingly, the plurality of link lines LL may be composed of a conductive material having excellent flexibility in order to reduce cracks when the bending area BA is bent. For example, the plurality of link lines LL may be composed of a conductive material having excellent flexibility, such as gold (Au), silver (Ag), aluminum (Al), or the like, but embodiments of the present disclosure are not limited thereto. In addition, the plurality of link lines LL may be configured as one of various conductive materials used in the display area AA. For example, the plurality of link lines LL may be composed of molybdenum (Mo), chromium (Cr), titanium (Ti), nickel (Ni), neodymium (Nd), copper (Cu), and an alloy of silver (Ag) and magnesium (Mg), or an alloy thereof, but embodiments of the present disclosure are not limited thereto. The plurality of link lines LL may be composed of a multilayer structure including various conductive materials. For example, the plurality of link lines LL may be composed of a triple layer structure of titanium (Ti)/aluminum (Al)/titanium (Ti), but embodiments of the present disclosure are not limited thereto.

The plurality of link lines LL may be configured in various shapes to reduce stress. At least a portion of the plurality of link lines LL disposed on the bending area BA may extend in a same direction as an extension direction of the bending area BA, or may extend in a direction different from the extension direction of the bending area BA to reduce stress. For example, when the bending area BA extends in one direction from the first non-display area NA1 toward the second non-display area NA2, the at least the portion of the link lines LL disposed on the bending area BA may extend in a direction inclined with respect to the one direction. As another example, the at least the portion of the plurality of link lines LL may be configured in patterns of various shapes. For example, the at least the portion of the plurality of link lines LL disposed on the bending area BA may have a shape in which conductive patterns having at least one shape of a diamond shape, a rhombus shape, a trapezoidal wave shape, a triangular wave shape, a sawtooth wave shape, a sine wave shape, a circular shape, and an omega (52) shape are repeatedly disposed, but embodiments of the present disclosure are not limited thereto. Accordingly, in order to minimize or at least reduce stress concentrated on the plurality of link lines LL and cracks resulting therefrom, the shapes of the plurality of link lines LL may be formed in various shapes including the above-described shapes, but embodiments of the present disclosure are not limited thereto.

According to an embodiment of the present disclosure, a width of the second non-display area NA2 in which the plurality of pad electrodes PE are disposed may be wider than a width of the bending area BA in which only the plurality of link lines LL are disposed. In addition, a width of the display area AA in which the plurality of sub-pixels are disposed may be wider than the width of the bending area BA in which only the plurality of link lines LL are disposed. Although the width of the bending area BA is illustrated as being narrower than a width of other area of the substrate 110 in the drawings, a shape of the substrate 110 including the bending area BA may be exemplary, and embodiments of the present disclosure are not limited thereto.

The pad portion PAD including the plurality of pad electrodes PE may be disposed at the second non-display area NA2. The one or more flexible circuit boards (or flexible films) 310 may be attached or bonded to the pad portion PAD. The plurality of pad electrodes PE of the pad portion PAD may be electrically connected to the one or more flexible circuit boards (or flexible films) 310 and may transmit various signals (or power) received from the printed circuit board 330 and the flexible circuit board (or flexible film) 310 to the plurality of pixel driving circuits PD of the display area AA.

The flexible circuit board (or flexible film) 310 may be a film in which various components are disposed on a base film having flexibility. For example, the driving integrated circuit 311 including one or more of a gate driver integrated circuit and a data driver integrated circuit may be disposed at the flexible circuit board (or flexible film) 310, but embodiments of the present disclosure are not limited thereto. The driving integrated circuit 311 may be a component that processes data and a driving signal for displaying an image. The driving integrated circuit 311 may be disposed in a manner such as a chip on glass (COG), a chip on film (COF), or a tape carrier package (TCP) based on a mounting method, but embodiments of the present disclosure are not limited thereto. The flexible circuit board (or flexible film) 310 may be attached or bonded on the plurality of pad electrodes PE through a conductive adhesive layer, but embodiments of the present disclosure are not limited thereto.

The printed circuit board 330 is electrically connected to one or more flexible circuit boards (or flexible films) 310 and may be a component that supplies signals to the driving integrated circuit 311. The printed circuit board 330 may be disposed on one side of the flexible circuit board (or flexible film) 310 and may be electrically connected to the flexible circuit board (or flexible film) 310. Circuit components such as a memory or various passive circuit elements or the like for supplying various signals to the driving integrated circuit 311 may be additionally disposed at the printed circuit board 330.

The driving circuit part 300 according to an embodiment of the present disclosure may further include a timing controller 350 and a power management integrated circuit (PMIC) 370.

The timing controller 350 may be mounted on a printed circuit board 330. The timing controller 350 receives image data and a timing synchronization signal provided from a host control part, converts the image data into pixel data and provides the pixel data to the driving integrated circuit 311, and controls the driving timing of each of the driving integrated circuit 311 and the plurality of pixel driving circuits PD based on the timing synchronization signal.

The power management integrated circuit 370 may be configured to generate and output various powers for driving the display apparatus 1000. For example, the power management integrated circuit 370 may be configured to generate and output a power voltage, a reference voltage, a cathode-on voltage, a cathode-off voltage, or the like according to the control of the timing controller 350 based on the input power. For example, the power (or driving) voltage may be a voltage for driving a driving circuit or an integrated circuit. The reference voltage may be a voltage for controlling (or determining) brightness (or luminance) of an image displayed in the display area AA or light emitted from the light emitting device. The cathode-on voltage may be a voltage for turning on (or emitting) the light emitting device. The cathode-off voltage may be a voltage for turning off the light emitting device. For example, the cathode-on voltage may be a first common voltage or a first low-potential power voltage, and the cathode-off voltage may be a second common voltage or a second low-potential power voltage, but embodiments of the present disclosure are not limited thereto. For example, the driving circuit part 300 is configured to vary the reference voltage and the cathode-off voltage based on screen brightness set by the user (or user's touch).

The driving circuit part 300 according to an embodiment of the present disclosure may further include a touch integrated circuit 390.

The touch integrated circuit 390 may be configured to be electrically connected to the touch electrodes in the touch panel 200. The touch integrated circuit 390 may supply a touch driving signal to the touch electrodes in response to a touch synchronization signal supplied from the timing controller 350, generate touch raw data corresponding to a change in capacitance on the touch electrodes, and provide the generated touch raw data to the timing controller 350 or the host control part, but embodiments of the present disclosure are not limited thereto. For example, the touch integrated circuit 390 may be configured to generate touch coordinate data based on the touch raw data and provide the touch coordinate data to the host control part. For example, the touch integrated circuit 390 may be integrated or built into the driving integrated circuit 311.

The timing controller 350 may be configured to control voltages output from the power management integrated circuit 370 based on user touch information provided from the touch integrated circuit 390 or the host control part. For example, when a user adjusts a screen brightness (or luminance) of the display apparatus 1000 through the touch panel 200 or button operation, the timing controller 350 may be configured to provide reference voltage data and the cathode-off voltage data (or second common voltage data) to the power management integrated circuit 370 based on screen brightness data corresponding to the screen brightness according to the user operation (or setting). The power management integrated circuit 370 may be configured to generate and output the reference voltage and the cathode-off voltage based on each of the reference voltage data and the cathode-off voltage data provided from the timing controller 350.

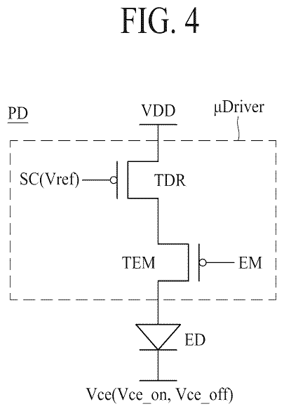

FIG. 4 is a diagram illustrating a circuit structure according to an embodiment of the present disclosure. FIG. 4 is a diagram illustrating one micro-driver included in each of the plurality of pixel driving circuits illustrated in FIG. 3.

In FIG. 4, one light emitting device ED is connected to one micro-driver (μDriver) as an example, but is not limited thereto. For example, 8 light emitting devices ED may be connected to the one micro-driver (uDriver). For example, 8 light emitting devices ED in different lines (or horizontal lines or row lines) may be connected to the one micro-driver (uDriver). In another example, 16 light emitting devices ED may be connected to the one micro-driver (uDriver), or 32 light emitting devices ED or 64 light emitting devices ED may be simultaneously (or commonly) connected to the one micro-driver (uDriver). For example, the micro-driver (uDriver) may be a sub-driver (uDriver). For example, the light emitting device ED may be a micro light emitting device, a micro light emitting diode, or a micro light emitting diode chip. For example, the light emitting device ED may have a scale of 1 μm to 100 μm, but embodiments of the present disclosure are not limited thereto.

The one micro-driver (uDriver) may be configured to apply a driving current (or data current) based on a scan signal (or reference voltage) and an emission signal to the light emitting device ED. The one micro-driver (uDriver) according to an embodiment of the present disclosure may include a driving transistor TDR and a light emitting transistor TEM, but embodiments of the present disclosure are not limited thereto.

According to an embodiment of the present disclosure, a high-potential power voltage VDD may be applied to a first electrode of the driving transistor TDR, a first electrode of the light emitting transistor TEM may be connected to a second electrode of the driving transistor TDR, and a scan signal SC may be applied to a gate electrode of the driving transistor TDR. The scan signal SC applied to the gate electrode of the driving transistor TDR is a direct current DC power, and a fixed reference voltage Vref may be applied for each frame, but embodiments of the present disclosure are not limited thereto. For example, the reference voltage Vref may be changed for one or more frames. For example, the reference voltage Vref may be adjusted (or varied) based on the screen brightness according to the user operation (or setting).

According to an embodiment of the present disclosure, the second electrode of the driving transistor TDR may be connected to the first electrode of the light emitting transistor TEM, the light emitting device ED may be connected to a second electrode of the light emitting transistor TEM, and the emission signal EM may be applied to a gate electrode of the light emitting transistor TEM. The emission signal EM applied to the gate electrode of the light emitting transistor TEM may be a pulse width modulation PWM signal that varies for each frame, but embodiments of the present disclosure are not limited thereto. For example, the emission signal EM may include a duty-on period that turns on the light emitting transistor TEM and a duty-off period that turns off the light emitting transistor TEM. For example, the duty-on period of the emission signal EM may be set (or adjusted) by a grayscale corresponding to pixel data.

A first electrode of the light emitting device ED may be connected to the second electrode of the light emitting transistor TEM, and a second electrode of the light emitting device ED may be connected to a low-potential power line. For example, the first electrode of the light emitting device ED may be an anode electrode or an anode terminal, and the second electrode of the light emitting device ED may be a cathode electrode or a cathode terminal, but embodiments of the present disclosure are not limited thereto. For example, the voltage applied from the light emitting transistor TEM to the first electrode of the light emitting device ED may be an anode voltage. For example, the voltage applied to the low-potential power line may be a cathode voltage Vce. For example, the voltage applied to the low-voltage power line may be a cathode-on voltage Vce_on or a cathode-off voltage Vce_off. For example, one or more of the cathode-on voltage Vce_on and the cathode-off voltage Vce_off may be varied (or adjusted). For example, one or more of the cathode-on voltage Vce_on and the cathode-off voltage Vce_off may be varied (or adjusted) according to the screen brightness according to user operation (or setting). For example, one or more of the cathode-on voltage Vce_on and the cathode-off voltage Vce_off may be varied (or adjusted) according to the reference voltage Vref.

Each of the driving transistor TDR and the light emitting transistor TEM may be an n-type transistor or a p-type transistor.

In the micro-driver (uDriver), the driving transistor TDR may be turned on by the scan signal SC applied from the pixel driving circuit PD, and the light emitting transistor TEM may be turned on by the emission signal EM applied from the pixel driving circuit PD. Accordingly, the driving current is applied to the light emitting device ED through the driving transistor TDR and the light emitting transistor TEM by the high-potential power voltage VDD applied to the first electrode of the driving transistor TDR, and thus, the light emitting device ED may emit light. For example, the light emitting device ED may emit light while the cathode-on voltage Vce_on is applied to the low-potential power line, and may not emit light while the cathode-off voltage Vce_off is applied to the low-potential power line.

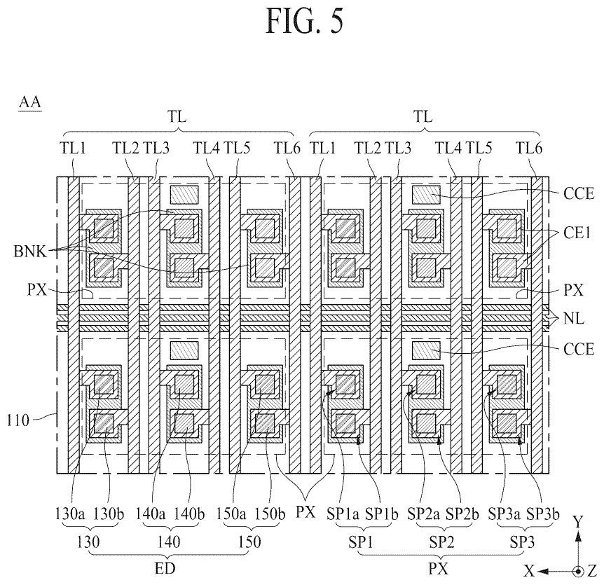

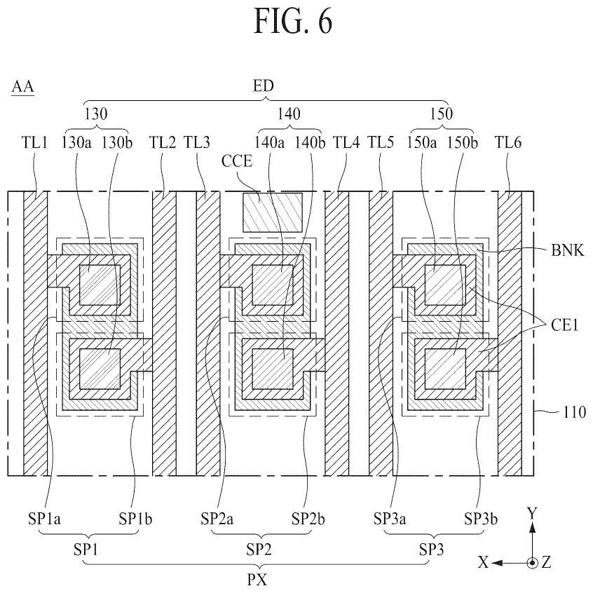

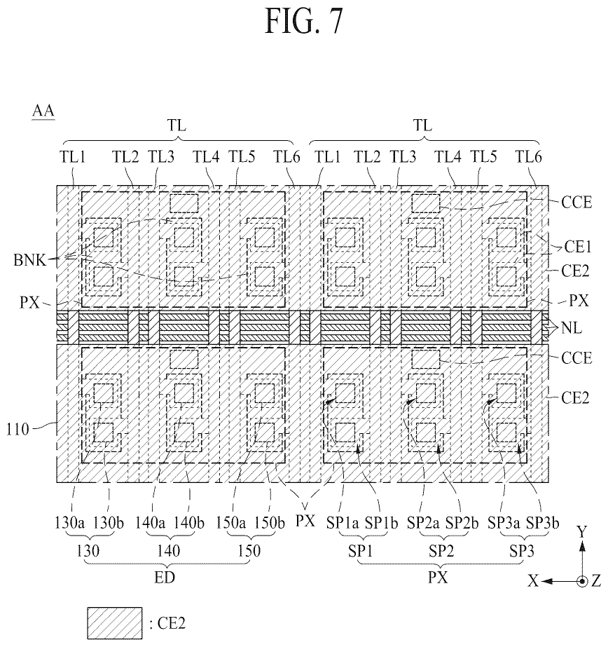

FIGS. 5 to 7 are plan views of a display apparatus according to an embodiment of the present disclosure. For example, FIG. 5 is an enlarged view of a display area including a plurality of pixels. For example, FIG. 6 is an enlarged view of a display area including one pixel. For example, FIG. 7 is an enlarged view of a display area including a plurality of pixels.

FIGS. 5 and 6 illustrate a plurality of signal lines TL, a plurality of communication lines NL, a plurality of first electrodes CE1, a plurality of banks BNK, and a plurality of light emitting devices ED, but embodiments of the present disclosure are not limited thereto. FIG. 7 is an enlarged plan view in which the plurality of second electrodes CE2 are additionally disposed in FIG. 5, for convenience, an area overlapping the second electrodes CE2 is indicated with a dotted line.

Referring to FIGS. 5 to 7, a plurality of pixels PX composed of a plurality of sub-pixels may be disposed in a display area AA. Each of the plurality of sub-pixels includes a light emitting device ED and may independently emit light. The plurality of sub-pixels may be configured in a plurality of rows and a plurality of columns and may be disposed in a matrix form, but embodiments of the present disclosure are not limited thereto.

The plurality of sub-pixels may include a first sub-pixel SP1, a second sub-pixel SP2, and a third sub-pixel SP3. For example, the plurality of sub-pixels may include the first sub-pixel SP1, the second sub-pixel SP2, and the third sub-pixel SP3 disposed along a row direction (or a first direction X). For example, any one sub-pixel of the first sub-pixel SP1, the second sub-pixel SP2, and the third sub-pixel SP3 may be a red sub-pixel, another sub-pixel may be a green sub-pixel, and the other sub-pixel may be a blue sub-pixel. The types of the plurality of sub-pixels are exemplary, and embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3.

The pair of first sub-pixels SP1 may be composed of a 1-1^{th} sub-pixel SP1a and a 1-2^{th} sub-pixel SP1b. The pair of second sub-pixels SP2 may be composed of a 2-1^{th} sub-pixel SP2a and a 2-2^{th} sub-pixel SP2b. The pair of third sub-pixels SP3 may be composed of a 3-1th sub-pixel SP3a and a 3-2^{th} sub-pixel SP3b. For example, one pixel PX may include the 1-1th sub-pixel SP1a, the 1-2^{th} sub-pixel SP1b, the 2-1^{th} sub-pixel SP2a, the 2-2^{th} sub-pixel SP2b, the 3-1^{th} sub-pixel SP3a, and the 3-2^{th} sub-pixel SP3b, but embodiments of the present disclosure are not limited thereto.

The plurality of sub-pixels composing one pixel PX may be variously arranged. For example, in the one pixel PX, the pair of first sub-pixels SP1 may be disposed in a same column, the pair of second sub-pixels SP2 may be disposed in a same column, and the pair of third sub-pixels SP3 may be disposed in a same column. The first sub-pixel SP1, the second sub-pixel SP2, and the third sub-pixel SP3 may be disposed in a same row. The number and arrangement of the plurality of sub-pixels composing the one pixel PX are exemplary, and embodiments of the present disclosure are not limited thereto.

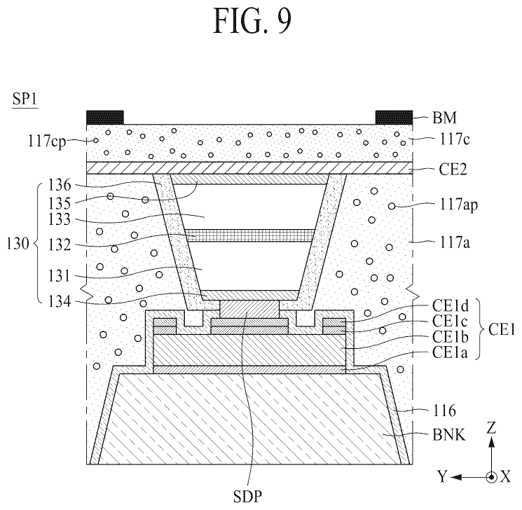

The plurality of signal lines TL may be disposed at an area between the plurality of sub-pixels. The plurality of signal lines TL may extend in a column direction (or a second direction Y) at the area between the plurality of sub-pixels. The plurality of signal lines TL may be lines that transmit an anode voltage from a pixel driving circuit (PD illustrated in FIG. 3 or a micro-driver (uDriver)) to the plurality of sub-pixels. For example, the plurality of signal lines TL may be electrically connected to the plurality of pixel driving circuits (PD illustrated in FIG. 3) and first electrodes CE1 of the plurality of sub-pixels. The anode voltage output from the pixel driving circuit (PD illustrated in FIG. 3) may be transmitted to the first electrodes CE1 of the plurality of sub-pixels through the plurality of signal lines TL. For example, the first electrode CE1 may be an electrode that is electrically connected to an anode electrode (134 illustrated in FIG. 9) of the light emitting device ED. Accordingly, the anode voltage from the signal line TL can be transmitted to the anode electrode (134 illustrated in FIG. 9) of the light emitting device ED through the first electrode CE1. For example, the first electrode CE1 may be a connection electrode, a connection electrode pattern, or a connection pattern.

Therefore, instead of forming a plurality of transistors and storage capacitors in each of the plurality of sub-pixels, a structure of the display apparatus 1000 may be simplified by using the pixel driving circuit (PD illustrated in FIG. 3) in which the plurality of pixel circuits are integrated. In addition, since the circuits disposed at each of the plurality of sub-pixels are integrated in one pixel driving circuit (PD illustrated in FIG. 3), high-efficiency and low-power driving may be possible.

The plurality of signal lines TL may include a first signal line TL1, a second signal line TL2, a third signal line TL3, a fourth signal line TLA, a fifth signal line TL5, and a sixth signal line TL6. Each of the first signal line TL1 and the second signal line TL2 may be electrically connected to each of the pair of first sub-pixels SP1. Each of the third signal line TL3 and the fourth signal line TL4 may be electrically connected to each of the pair of second sub-pixels SP2. Each of the fifth signal line TL5 and the sixth signal line TL6 may be electrically connected to each of the pair of third sub-pixels SP3.

The first signal line TL1 may be disposed at one side of the pair of first sub-pixels SP1, and the second signal line TL2 may be disposed at another side of the pair of first sub-pixels SP1. The first signal line TL1 may be electrically connected to a first electrode CE1 of one first sub-pixel SP1 (for example, the 1-1^{th} sub-pixel SP1a) of the pair of first sub-pixels SP1. The second signal line TL2 may be electrically connected to a first electrode CE1 of the other first sub-pixel SP1 (for example, the 1-2^{th} sub-pixel SP1b) of the pair of first sub-pixels SP1.

The third signal line TL3 may be disposed at one side of the pair of second sub-pixels SP2, and the fourth signal line TL4 may be disposed at another side of the pair of second sub-pixels SP2. For example, the third signal line TL3 may be disposed adjacent to the second signal line TL2. The third signal line TL3 may be electrically connected to a first electrode CE1 of one second sub-pixel SP2 (for example, the 2-1^{th} sub-pixel SP2a) of the pair of second sub-pixels SP2. The fourth signal line TL4 may be electrically connected to a first electrode CE1 of the other second sub-pixel SP2 (for example, the 2-2^{th} sub-pixel SP2b) of the pair of second sub-pixels SP2.

The fifth signal line TL5 may be disposed at one side of the pair of third sub-pixels SP3, and the sixth signal line TL6 may be disposed at another side of the pair of third sub-pixels SP3. For example, the fifth signal line TL5 may be disposed adjacent to the fourth signal line TLA. The sixth signal line TL6 may be disposed adjacent to the first signal line TL1 connected to the adjacent pixel PX. The fifth signal line TL5 may be electrically connected to a first electrode CE1 of one third sub-pixel SP3 (for example, the 3-1^{th} sub-pixel SP3a) of the pair of third sub-pixels SP3. The sixth signal line TL6 may be electrically connected to a first electrode CE1 of the other third sub-pixel SP3 (for example, the 3-2^{th} sub-pixel SP3b) of the pair of third sub-pixels SP3.

The plurality of signal lines TL may be made of a conductive material. For example, the plurality of signal lines TL may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but embodiments of the present disclosure are not limited thereto. For another example, the plurality of signal lines TL may be made of a multilayer structure of conductive materials. For example, the plurality of signal lines TL may be made of a multilayer structure of titanium (Ti)/aluminum (Al)/titanium (Ti)/indium tin oxide (ITO), but embodiments of the present disclosure are not limited thereto.

The plurality of communication lines NL may be disposed at an area between the plurality of pixels PX. The plurality of communication lines NL may be disposed to extend in the row direction at the area between the plurality of pixels PX. The plurality of communication lines NL are disposed at an area between the plurality of second electrodes CE2 and may not overlap the plurality of second electrodes CE2. For example, the plurality of communication lines NL may be lines (or wirings) used for short-range communication such as near field communication (NFC). The plurality of communication lines NL may function as antennas. For example, the plurality of communication lines NL may be a plurality of connection lines, but embodiments of the present disclosure are not limited thereto.

According to an embodiment of the present disclosure, a bank BNK may be disposed at each of the plurality of sub-pixels. A plurality of banks BNK may be structures on which the plurality of light emitting devices ED are mounted. The plurality of banks BNK may guide positions of the plurality of light emitting devices ED in a transfer process of transferring the plurality of light emitting devices ED. In the transfer process of the plurality of light emitting devices ED, the plurality of light emitting devices ED may be transferred onto the plurality of banks BNK. An entire area of the light emitting device ED may overlap the bank BNK. For example, in a plan view, an entire size of the light emitting device ED may be smaller than the bank BNK. For example, the plurality of banks BNK may be bank patterns, structures, or protruding patterns, or the like, but embodiments of the present disclosure are not limited thereto.

The bank BNK of the first sub-pixel SP1, the bank BNK of the second sub-pixel SP2, and the bank BNK of the third sub-pixel SP3 may be disposed to be spaced apart from each other along the row direction (or the second direction Y). The bank BNK of the first sub-pixel SP1, the bank BNK of the second sub-pixel SP2, and the bank BNK of the third sub-pixel SP3 may be configured to be separated from each other. Accordingly, in a process of transferring the light emitting device to the sub-pixel, the banks BNK of the first sub-pixel SP1, the second sub-pixel SP2, and the third sub-pixel SP3, to which different types of light emitting devices ED are transferred, may be easily identified, so that transfer defects in the transfer process of the light emitting devices may be prevented or minimized.

According to an embodiment of the present disclosure, the bank BNK of the 1-1th sub-pixel SP1a and the bank BNK of the 1-2^{th} sub-pixel SP1b may be connected to each other, or may be formed to be spaced apart or separated from each other. For example, considering the design of the transfer process requirements, or the like, the bank BNK of the 1-1^{th} sub-pixel SP1a and the bank BNK of the 1-2^{th} sub-pixel SP1b, in which a same type of light emitting device ED is disposed, may be connected to each other, or may be spaced apart or separated from each other. In addition, the bank BNK of the 2-1^{th} sub-pixel SP2a and the bank BNK of the 2-2^{th} sub-pixel SP2b may be connected to each other, or may be formed to be spaced apart or separated from each other. The bank BNK of the 3-1^{th} sub-pixel SP3a and the bank BNK of the 3-2^{th} sub-pixel SP3b may be connected to each other or may be formed to be spaced apart or separated from each other. Therefore, the bank BNK of the pair of first sub-pixels SP1, the bank BNK of the pair of second sub-pixels SP2, and the bank BNK of the pair of third sub-pixels SP3 may be formed in various ways, but embodiments of the present disclosure are not limited thereto.

According to an embodiment of the present disclosure, the plurality of banks BNK may be made of an organic insulating material. The plurality of banks BNK may be composed of a single layer or multiple layers of the organic insulating material. For example, the plurality of banks BNK may be composed of a photo resist, a polyimide (PI), or an acrylic-based material, or the like, but embodiments of the present disclosure are not limited thereto.

The first electrode CE1 may be disposed at each of the plurality of sub-pixels. The first electrode CE1 may be disposed on the bank BNK while overlapping the bank BNK. The first electrode CE1 may be electrically connected to one of the plurality of signal lines TL. At least a portion of the first electrode CE1 may extend to an outside the bank BNK and be electrically connected to the signal line TL closest to the first electrode CE1. The portion of the first electrode CE1 may overlap the bank BNK, and the remaining portion of the first electrode CE1 may not overlap (e.g., non-overlapping) the bank BNK.

According to an embodiment of the present disclosure, a portion of the first electrode CE1 of the 1-1^{th} sub-pixel SP1a may extend to one side of the 1-1^{th} sub-pixel SP1a and may be electrically connected to the first signal line TL1, and a portion of the first electrode CE1 of the 1-2^{th} sub-pixel SP1b may extend to the other side of the 1-2^{th} sub-pixel SP1b and may be electrically connected to the second signal line TL2. A portion of the first electrode CE1 of the 2-1^{th} sub-pixel SP2a may extend to one side of the 2-1^{th} sub-pixel SP2a and may be electrically connected to the third signal line TL3, and a portion of the first electrode CEL of the 2-2^{th} sub-pixel SP2b may extend to the other side of the 2-2^{th} sub-pixel SP2b and may be electrically connected to the fourth signal line TL4. A portion of the first electrode CE1 of the 3-1^{th} sub-pixel SP3a may extend to one side of the 3-1^{th} sub-pixel SP3a and may be electrically connected to the fifth signal line TL5, and a portion of the first electrode CE of the 3-2^{th} sub-pixel SP3b may extend to the other side of the 3-2^{th} sub-pixel SP3b and may be electrically connected to the sixth signal line TL6.

The first electrode CE1 may be electrically connected to the anode electrode (or anode terminal) (134 illustrated in FIG. 9) of the light emitting device ED. The anode voltage from the pixel driving circuit (PD illustrated in FIG. 3) may be sequentially transmitted to the light emitting device ED through the signal line TL and the first electrode CE1. The pixel driving circuit (PD illustrated in FIG. 3) may apply a same voltage (or anode voltage) to the first electrode CE1 of each of the plurality of sub-pixels, but embodiments of the present disclosure are not limited thereto. For example, the pixel driving circuit (PD illustrated in FIG. 3) may be configured to apply different voltages to the first electrode CE of each of the plurality of sub-pixels based on an image displayed on the corresponding sub-pixel. For example, different voltages may be applied to the first electrodes CE1 of each of the plurality of sub-pixels. Accordingly, the first electrode CE1 may be a pixel electrode, but embodiments of the present disclosure are not limited thereto.

The first electrode CE1 may be composed of a conductive material. For example, the first electrode CE1 may be formed integrally with the plurality of signal lines TL. For example, the first electrode CE1 may be composed of a same conductive material as the plurality of signal lines TL, but embodiments of the present disclosure are not limited thereto. As an embodiment of the present disclosure, the first electrode CE1 may be composed of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like, but embodiments of the present disclosure are not limited thereto. As another embodiment of the present disclosure, the first electrode CE1 may be composed of a multilayer structure of a conductive material. For example, the plurality of first electrodes CE1 may be composed of a multilayer structure of titanium (Ti)/aluminum (Al)/titanium (Ti)/indium tin oxide (ITO), but embodiments of the present disclosure are not limited thereto.

The plurality of light emitting devices ED may be disposed at the first electrode CE1 so as to overlap the bank BNK and the first electrode CE1. An entire area of the plurality of light emitting devices ED may overlap the bank BNK and the first electrode CE1. The plurality of light emitting devices ED may be in contact with the first electrode CE1 so as to overlap the bank BNK and the first electrode CE1.

The plurality of light emitting devices ED may disposed at the first electrode CE1 and may be electrically connected to the first electrode CE1. Therefore, the light emitting devices ED may emit light by receiving the anode voltage from the pixel driving circuit PD through the signal line TL and the first electrode CE1.

The plurality of light emitting devices ED may include a first light emitting device 130, a second light emitting device 140, and a third light emitting device 150.

The first light emitting device 130 may be disposed at the first sub-pixel SP1. The second light emitting device 140 may be disposed at the second sub-pixel SP2. The third light emitting device 150 may be disposed at the third sub-pixel SP3. For example, any one of the first light emitting device 130, the second light emitting device 140, and the third light emitting device 150 may be a red light emitting device, another light emitting device may be a green light emitting device, and the other light emitting device may be a blue light emitting device, but embodiments of the present disclosure are not limited thereto. Accordingly, red light, green light, and blue light emitted from the plurality of light emitting devices ED may be combined to implement various colors of light including white. The types of the plurality of light emitting devices ED are exemplary, but embodiments of the present disclosure are not limited thereto.

The first light emitting device 130 may include a 1-1^{th} light emitting device 130a disposed at a 1-1^{th} sub-pixel SP1a and a 1-2^{th} light emitting device 130b disposed at a 1-2^{th} sub-pixel SP1b. The second light emitting device 140 may include a 2-1^{th} light emitting device 140a disposed at a 2-1^{th} sub-pixel SP2a and a 2-2^{th} light emitting device 140b disposed at a 2-2^{th} sub-pixel SP2b. The third light emitting device 150 may include a 3-1^{th} light emitting device 150a disposed at a 3-1^{th} sub-pixel SP3a and a 3-2^{th} light emitting device 150b disposed at a 3-2^{th} sub-pixel SP3b.

A second electrode CE2 may be disposed at each of the plurality of sub-pixels. The second electrode CE2 may be disposed over the light emitting device ED. The second electrode CE2 may be electrically connected to the pixel driving circuit (PD illustrated in FIG. 3) through a plurality of contact electrodes CCE. The second electrode CE2 may be electrically connected to a cathode electrode (or cathode terminal) (135 illustrated in FIG. 9) of the light emitting device ED to transmit a cathode voltage (or low-potential power voltage) from the pixel driving circuit (PD illustrated in FIG. 3) to the light emitting device ED.

According to an embodiment of the present disclosure, the cathode voltage applied to the second electrode CE2 of each of the plurality of sub-pixels may be a same. For example, the cathode voltage may be commonly applied to the second electrode CE2 of each of the plurality of sub-pixels and the cathode electrode (135 illustrated in FIG. 9) of the light emitting device ED. Accordingly, the second electrode CE2 may be a common electrode, a common electrode pattern, a common cathode electrode, a common cathode electrode pattern, a common divided electrode, or a common divided electrode pattern, but embodiments of the present disclosure are not limited thereto.

According to another embodiment of the present disclosure, the cathode voltage applied to the second electrode CE2 of each of the plurality of sub-pixels may be changed based on a reference voltage (Vref illustrated in FIG. 4). For example, the cathode voltage may be adjusted (or varied) according to screen brightness based on a user operation (or setting).

The second electrode CE2 according to an embodiment of the present disclosure may have a size corresponding to one row (or a horizontal line). For example, the second electrode CE2 may have a width corresponding to one row (or a horizontal line) and may extend along the row direction (or the first direction X). For example, the second electrode CE2 may be commonly connected to the light emitting device ED in each of the plurality of pixels PX disposed along the row direction. For example, the second electrode CE2 may be commonly connected to a cathode electrode (or cathode terminal) (135 illustrated in FIG. 9) of the light emitting device ED in each of 16 pixels PX disposed along the row direction, but embodiments of the present disclosure are not limited thereto. For example, the second electrode CE2 may be commonly connected to the cathode electrode (or cathode terminal) (135 illustrated in FIG. 9) of 96 light emitting devices ED disposed along the row direction, but embodiments of the present disclosure are not limited thereto. For example, the second electrode CE2 may be commonly connected to the cathode electrode (or cathode terminal) (135 illustrated in FIG. 9) of 192 light emitting devices ED in one row (or horizontal line), but embodiments of the present disclosure are not limited thereto.

According to another embodiment of the present disclosure, some of the second electrodes CE2 of each of the plurality of sub-pixels may be disposed to be spaced apart from or separated from each other. For example, the second electrodes CE2 connected to the pixels PX of a n^{th} row and the second electrodes CE2 connected to the pixels PX of a n+1^{th} row may be disposed to be spaced apart from or separated from each other. As an embodiment of the present disclosure, the plurality of second electrodes CE2 may be disposed to be spaced apart from each other with a plurality of communication lines NL extending in the row direction therebetween. Accordingly, the number of the plurality of sub-pixels may be greater than the number of the plurality of second electrodes CE2.

The plurality of second electrodes CE2 may be composed of a transparent conductive material, but embodiments of the present disclosure are not limited thereto. The plurality of second electrodes CE2 may be composed of a transparent conductive material so that light emitted from the light emitting device ED may be directed toward an upper portion of the second electrodes CE2. For example, the second electrodes CE2 may be composed of a transparent conductive material such as indium tin oxide (ITO), indium zinc oxide (IZO), indium gallium zinc oxide (IGZO), or the like, but embodiments of the present disclosure are not limited thereto.

The plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

The plurality of contact electrodes CCE may be electrically connected to the plurality of second electrodes CE2. The plurality of contact electrodes CCE may be disposed between the substrate 110 and the plurality of second electrodes CE2 and configured to transmit a cathode voltage supplied from the pixel driving circuit (PD illustrated in FIG. 3) through a low-potential power line to the second electrodes CE2.

According to an embodiment of the present disclosure, when the light emitting device ED is configured as a micro light emitting diode chip, a plurality of micro light emitting diode chips may be formed on a wafer, and the micro light emitting diode chips may be transferred to a substrate 110 to manufacture a display panel 100. In the process of transferring a plurality of light emitting devices ED having a micro size (or fine size) from the wafer to the substrate 110, various defects may occur. For example, in some sub-pixels, a defect may occur in which the light emitting device ED is not transferred, and in other sub-pixels, a defect may occur in which the light emitting device ED is transferred out of its proper position due to an alignment error. In addition, the transfer process may proceed normally, but the transferred light emitting device ED itself may be defective. Therefore, in consideration of defects that may occur during the transfer process of the plurality of light emitting devices ED, a plurality of light emitting devices ED of a same type may be transferred to one sub-pixel. A lighting test of the plurality of light emitting devices ED may be performed, and only one light emitting device ED that is finally determined to be normal may be used.

According to an embodiment of the present disclosure, the 1-1^{th} light emitting device 130a and the 1-2^{th} light emitting device 130b may be transferred together to one pixel PX, and may be inspected for defects therein. As an embodiment of the present disclosure, when the 1-1^{th} light emitting device 130a and the 1-2^{th} light emitting device 130b are determined to be normal, only the 1-1^{th} light emitting device 130a may be used, and the 1-2th light emitting device 130b may be unused. In another embodiment of the present disclosure, if only the 1-2 light emitting device 130b among the 1-1 light emitting device 130a and the 1-2 light emitting device 130b is determined to be normal, the 1-1 light emitting device 130a is not used, and only the 1-2 light emitting device 130b may be used. Therefore, even if multiple light emitting devices EDs of the same type are transferred to one pixel PX, only one light emitting device ED may ultimately be used.

According to an embodiment of the present disclosure, any one of a pair of light emitting devices ED may be a main (or a primary) light emitting device ED, and the other light emitting device ED may be a redundancy light emitting device ED. The redundancy light emitting device ED may be a spare light emitting device ED that is transferred in preparation for a failure of the main light emitting device ED. When the main light emitting device ED fails, the redundancy light emitting device ED may be used as a replacement for the main light emitting device ED. Therefore, by transferring the main light emitting device ED and the redundancy light emitting device ED together to one pixel PX, it is possible to minimize or at least reduce a deterioration in display quality due to a failure of the main light emitting device ED and the redundancy light emitting device ED. For example, the 1-1^{th} light emitting device 130a, the 2-1^{th} light emitting device 140a, and the 3-1^{th} light emitting device 150a transferred to one pixel PX may be used as the main light emitting device ED, and the 1-2^{th} light emitting device 130b, the 2-2^{th} light emitting device 140b, and the 3-2^{th} light emitting device 150b may be used as the redundancy light emitting device ED.

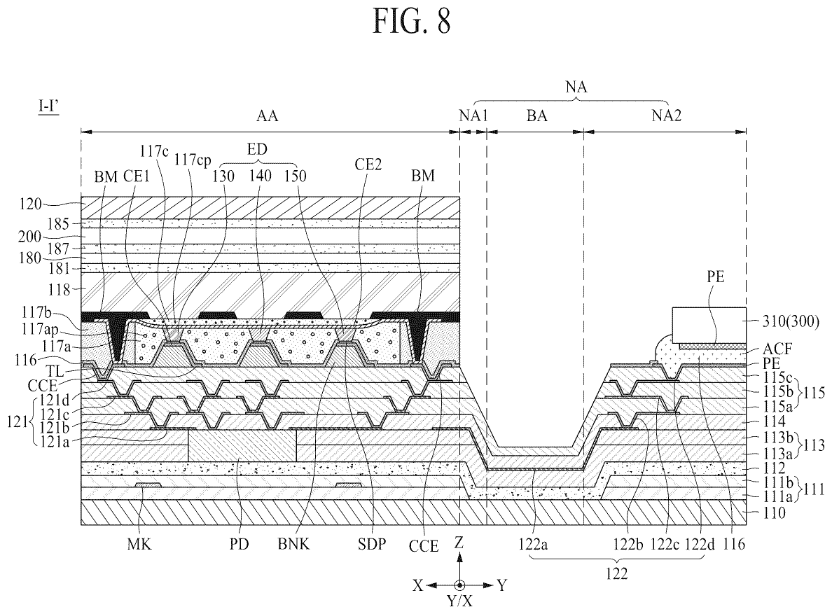

FIG. 8 is a cross-sectional view taken along line I-I′ illustrated in FIG. 2 according to an embodiment of the present disclosure. FIG. 9 is a cross-sectional view of a first light emitting device according to an embodiment of the present disclosure. For example, FIG. 8 is a cross-sectional view of a display area AA, a first non-display area NA, a bending area BA, and a second non-display area NA2 taken along line I-I′ illustrated in FIG. 2, and FIG. 9 is a cross-sectional view of a portion of the display area AA.

Referring to FIG. 8, a buffer layer 111 may be disposed at the remaining area of the substrate 110 excluding the bending area BA. The buffer layer 111 may include a first buffer layer 111a and a second buffer layer 111b.

The first buffer layer 111a and the second buffer layer 111b may be disposed at the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be composed of an inorganic insulating material. For example, the first buffer layer 111a and the second buffer layer 111b may be made of a single layer or multiple layers of silicon oxide (SiOx) or silicon nitride (SiNx), but embodiments of the present disclosure are not limited thereto.

According to an embodiment of the present disclosure, a portion of the first buffer layer 111a and the second buffer layer 111b on the bending area BA may be removed. An upper surface of the substrate 110 located at the bending area BA may be exposed without being covered by the first buffer layer 111a and the second buffer layer 111b. Since the portion of the first buffer layer 111a and the second buffer layer 111b made of an inorganic insulating material is removed at the bending area BA, cracks generated at the first buffer layer 111a and the second buffer layer 111b may be prevented or minimized when the bending area BA is bent.

A plurality of alignment keys MK may be disposed between the first buffer layer 111a and the second buffer layer 111b. The plurality of alignment keys MK may be configured to identify (or align) a position of pixel driving circuit PD during a manufacturing process of the display panel 100. For example, the plurality of alignment keys MK may be configured to align the position of pixel driving circuit PD transferred onto an adhesive layer 112. For example, the plurality of alignment keys MK may be omitted, but embodiments of the present disclosure are not limited thereto.

The adhesive layer 112 may be disposed on the second buffer layer 111b. The adhesive layer 112 may be disposed at the display area AA, the first non-display area NA1, the bending area BA, and the second non-display area NA2. For example, in the non-display areas NA1 and NA2 including the bending area BA, at least a portion of the adhesive layer 112 may be removed. For example, the adhesive layer 112 may be made of any one of a polymer, an epoxy resin, a UV-curable resin, a polyimide-based material, an acrylate-based material, a urethane-based material, and a polydimethylsiloxane (PDMS), but embodiments of the present disclosure are not limited thereto.

In the display area AA, the pixel driving circuit PD may be disposed on the adhesive layer 112. The driving circuit PD may be supported by the buffer layer 111. When the pixel driving circuit PD is implemented as a driving driver (or a driving driver integrated circuit or a driving driver chip), the driving driver may be mounted on the adhesive layer 112 by a transfer process, but embodiments of the present disclosure are not limited thereto.

A protective layer 113 may be disposed on the adhesive layer 112 and the pixel driving circuit PD. The protective layer 113 may include a first protective layer 113a and a second protective layer 113b. For example, the first protective layer 113a and the second protective layer 113b may be disposed on the adhesive layer 112 and the pixel driving circuit PD. The first protective layer 113a and the second protective layer 113b may be disposed to surround a side surface (or lateral surface) of the pixel driving circuit PD, but embodiments of the present disclosure are not limited thereto. For example, the second protective layer 113b may be disposed to cover at least a portion of an upper surface of the pixel driving circuit PD. For example, at least one of the first protective layer 113a and the second protective layer 113b disposed on the bending area BA may be omitted. For example, the first protective layer 113a may be entirely disposed at the display area AA and the non-display area NA, and the second protective layer 113b may be partially disposed at the display area AA, the first non-display area NA1, and the second non-display area NA2, and may not be disposed at the bending area BA. For example, the second protective layer 113b (or a portion of the first protective layer 113a) at the bending area BA may be removed, but embodiments of the present disclosure are not limited thereto.

The first protective layer 113a and the second protective layer 113b may be composed of an organic insulating material, but embodiments of the present disclosure are not limited thereto. For example, the first protective layer 113a and the second protective layer 113b may be composed of a photo resist, a polyimide (PI), or a photo acryl-based material, or the like, but embodiments of the present disclosure are not limited thereto. For example, the first protective layer 113a and the second protective layer 113b may be an overcoating layer, an inorganic insulating layer, or an organic insulating layer, but embodiments of the present disclosure are not limited thereto.

According to an embodiment of the present disclosure, a wiring layer (or pixel wiring layer) may be disposed on the protective layer 113 (or second protective layer 113b). For example, the wiring layer may be configured to surround or cover the pixel driving circuit PD. The wiring layer may include a plurality of first connection lines 121.

The plurality of first connection lines 121 may be disposed on the protective layer 113. For example, the plurality of first connection lines 121 may be disposed on the second protective layer 113b at the display area AA. The plurality of first connection lines 121 may be lines (or intermediate lines or jumping lines) configured to electrically connect the pixel driving circuit PD to other components and/or lines in different layers. For example, the pixel driving circuit PD may be electrically connected to a plurality of signal lines TL and a plurality of contact electrodes CCE, or the like through the plurality of first connection lines 121.

The plurality of first connection lines 121 may include a 1-1^{th} connection line 121a, a 1-2^{th} connection line 121b, a 1-3^{th} connection line 121c, and a 1-4^{th} connection line 121d, but embodiments of the present disclosure are not limited thereto. For example, the plurality of 1-1^{th} connection lines 121a may be disposed on the second protective layer 113b. The plurality of 1-1^{th} connection lines 121a may be configured to be electrically connected to the pixel driving circuit PD. The plurality of 1-1^{th} connection lines 121a may be configured to transmit a voltage output from the pixel driving circuit PD to the first electrode CEL or the second electrode CE2.

A third protective layer 114 may be disposed on the second protective layer 113b. The third protective layer 114 may be entirely disposed at the display area AA and the non-display area NA. In the bending area BA, the third protective layer 114 may cover or enclose side surfaces (or lateral surfaces) of the second protective layer 113b and the upper surface of the first protective layer 113a. The third protective layer 114 may be composed of an organic insulating material. For example, the third protective layer 114 may be composed of a photo resist, a polyimide (PI), or a photo acryl-based material, or the like, but embodiments of the present disclosure are not limited thereto. For example, the first protective layer 113a, the second protective layer 113b, and the third protective layer 114 may be composed of a same material, but embodiments of the present disclosure are not limited thereto.

The plurality of 1-2^{th} connection lines 121b may be disposed on the third protective layer 114. The plurality of 1-2^{th} connection lines 121b may be connected to the pixel driving circuit PD through the 1-1^{th} connection line 121a or may be directly connected to the pixel driving circuit PD. For example, a portion of the 1-2^{th} connection line 121b may be directly connected to the pixel driving circuit PD through a contact hole of the third protective layer 114. Another portion of the 1-2^{th} connection line 121b may be electrically connected to the 1-1^{th} connection line 121a through a contact hole of the third protective layer 114. However, embodiments of the present disclosure are not limited thereto. As an embodiment of the present disclosure, a voltage output from the pixel driving circuit PD may be transmitted to the first electrode CE1 or the second electrode CE2 through the plurality of 1-2^{th} connection lines 121b and other connection lines.

The display apparatus 1000 according to an embodiment of the present disclosure may further include an insulating layer 115 in the wiring layer. The insulating layer 115 may be configured to electrically insulate the plurality of first connection lines 121 and cover the plurality of first connection lines 121. For example, the insulating layer 115 may include a plurality of insulating layers 115a, 115b, and 115c or may include first to third insulating layers 115a, 115b, and 115c.

According to an embodiment of the present disclosure, the first insulating layer 115a may be disposed on the plurality of 1-2^{th} connection lines 121b. The first insulating layer 115a may be entirely disposed at the display area AA and the non-display area NA, but embodiments of the present disclosure are not limited thereto. The first insulating layer 115a may be composed of an organic insulating material, but embodiments of the present disclosure are not limited thereto. For example, the first insulating layer 115a may be composed of a photo resist, a polyimide (PI), or a photo acryl-based material, or the like, but embodiments of the present disclosure are not limited thereto.

The plurality of 1-3^{th} connection lines 121c may be disposed on the first insulating layer 115a. The plurality of 1-3^{th} connection lines 121c may be electrically connected to the plurality of 1-2^{th} connection lines 121b. For example, the 1-3^{th} connection line 121c may be electrically connected to the 1-2^{th} connection line 121b through a contact hole of the first insulating layer 115a.

A second insulating layer 115b may be disposed on the plurality of 1-3^{th} connection lines 121c. The second insulating layer 115b may be disposed at the remaining area except for the bending area BA, but embodiments of the present disclosure are not limited thereto. The second insulating layer 115b may be disposed at the display area AA, the first non-display area NA1, and the second non-display area NA2, but embodiments of the present disclosure are not limited thereto. For example, at least a portion of the second insulating layer 115b disposed at the bending area BA may be removed. The second insulating layer 115b may be composed of an organic insulating material, but embodiments of the present disclosure are not limited thereto. For example, the second insulating layer 115b may be composed of a photo resist, polyimide (PI), or photo acryl-based material, or the like, but embodiments of the present disclosure are not limited thereto.

The plurality of 1-4^{th} connection lines 121d may be disposed on the second insulating layer 115b. The plurality of 1-4^{th} connection lines 121d may be electrically connected to the plurality of 1-3^{th} connection lines 121c. For example, the 1-4^{th} connection line 121d may be electrically connected to the 1-3^{th} connection line 121c through a contact hole of the second insulating layer 115b.

The 1-4^{th} connection line 121d may be connected to the contact electrode CCE through a contact hole of the third insulating layer 115c, and accordingly, the contact electrode CCE and the pixel driving circuit PD may be electrically connected by the first connection line 121.

The 1-4^{th} connection line 121d may be directly connected to the signal line TL through a contact hole provided at the third insulating layer 115c or may be electrically connected to the signal line TL through another additional line or electrode, and accordingly, the signal line TL and the pixel driving circuit PD may be electrically connected by the first connection line 121.

A plurality of second connection lines 122 may be disposed on the protective layer 113 in the non-display area NA. For example, the plurality of second connection lines 122 may be disposed on the second protective layer 113b in the non-display area NA. The plurality of second connection lines 122 may be lines for transmitting signals transmitted from a flexible circuit board (or flexible film) (310 illustrated in FIG. 2) and a printed circuit board (330 illustrated in FIG. 2) through a pad portion (PAD illustrated in FIG. 2) to the pixel driving circuit PD in the display area AA.

According to an embodiment of the present disclosure, the plurality of second connection lines 122 may be electrically connected to a plurality of pad electrodes PE and may receive signals from the flexible circuit board (or flexible film) (310 illustrated in FIG. 2) and the printed circuit board (330 illustrated in FIG. 2).

According to an embodiment of the present disclosure, the plurality of second connection lines 122 may be configured to extend from the pad portion (PAD illustrated in FIG. 2) toward the display area AA and transmit the signals to the lines of the display area AA. In this case, the plurality of second connection lines 122 may function as link lines (LL illustrated in FIG. 3).

The plurality of second connection lines 122 may include a 2-1^{th} connection line 122a, a 2-2^{th} connection line 122b, a 2-3^{th} connection line 122c, and a 2-4^{th} connection line 122d.

A plurality of 2-1^{th} connection lines 122a may be disposed on the protection layer 113. For example, the plurality of 2-1^{th} connection lines 122a may be disposed on the second protection layer 113b. The plurality of 2-1^{th} connection lines 122a may extend from the second non-display area NA2 to the bending area BA and the first non-display area NA1. The plurality of 2-1^{th} connection lines 122a may be configured to transmit the signals transmitted from the flexible circuit board (or flexible film) (310 illustrated in FIG. 2) and the printed circuit board (330 illustrated in FIG. 2) through the pad portion (PAD illustrated in FIG. 2) to the pixel driving circuit PD of the display area AA.

According to an embodiment of the present disclosure, the plurality of 2-1th connection lines 122a may be electrically connected to the pad electrode PE and the pixel driving circuit PD, respectively. For example, the 2-1^{th} connection line 122a may extend to the display area AA and may be directly connected to the pixel driving circuit PD within the display area AA or may be electrically connected to the pixel driving circuit PD through other additional lines or electrodes. In addition, the 2-1^{th} connection line 122a may be electrically connected to the pad electrode PE within the second non-display area NA2 through the 2-2th connection line 122b, the 2-3^{th} connection line 122c, and the 2-4^{th} connection line 122d. Therefore, the pixel driving circuit PD and the pad electrode PE may be electrically connected by the 2-2^{th} connection lines 122.

A plurality of 2-2^{th} connection lines 122b may be disposed on the third protective layer 114. The plurality of 2-2^{th} connection lines 122b may be disposed at the second non-display area NA2. The 2-2^{th} connection line 122b may be electrically connected to the 2-1th connection line 122a through the contact hole of the third protective layer 114. Accordingly, signals from the flexible circuit board (or flexible film) (310 illustrated in FIG. 2) and the printed circuit board (330 illustrated in FIG. 2) may be transmitted to the 2-1^{th} connection line 122a through the 2-2^{th} connection line 122b.

The 2-3^{th} connection line 122c may be disposed on the first insulating layer 115a. The 2-3^{th} connection line 122c may be disposed at the second non-display area NA2. The 2-3^{th} connection line 122c may be electrically connected to the 2-2^{th} connection line 122b through the contact hole of the first insulating layer 115a. Therefore, signals from the flexible circuit board (or flexible film) (310 illustrated in FIG. 2) and the printed circuit board (330 illustrated in FIG. 2) may be transmitted to the 2-1^{th} connection line 122a through the 2-3^{th} connection line 122c and the 2-2^{th} connection line 122b.

The 2-4^{th} connection line 122d may be disposed on the second insulating layer 115b. The 2-4^{th} connection line 122d may be disposed at the second non-display area NA2. The 2-4^{th} connection line 122d may be electrically connected to the 2-3^{th} connection line 122c through the contact hole of the second insulating layer 115b. The 2-4^{th} connection line 122d may be electrically connected to the pad electrode PE through the contact hole of the third insulating layer 115c.

According to an embodiment of the present disclosure, signals from the flexible circuit board (or flexible film) (310 illustrated in FIG. 2) and the printed circuit board (330 illustrated in FIG. 2) may be transmitted to the 2-1^{th} connection line 122a through the 2-4th connection line 122d, the 2-3^{th} connection line 122c, and the 2-2^{th} connection line 122b.

The plurality of first connection lines 121 and the plurality of second connection lines 122 may be formed of any one of a conductive material having excellent ductility characteristics or various conductive materials used in the display area AA. As an embodiment of the present disclosure, the second connection line 122 in which a portion is disposed at the bending area BA may be formed of a conductive material having excellent ductility, such as gold (Au), silver (Ag), or aluminum (Al), but embodiments of the present disclosure are not limited thereto. As another embodiment of the present disclosure, the plurality of first connection lines 121 and the plurality of second connection lines 122 may be formed of molybdenum (Mo), chromium (Cr), titanium (Ti), nickel (Ni), neodymium (Nd), copper (Cu), and an alloy of silver (Ag) and magnesium (Mg), or an alloy thereof, but embodiments of the present disclosure are not limited thereto.

The third insulating layer 115c may be disposed on the plurality of first connection lines 121 and the plurality of second connection lines 122. The third insulating layer 115c may be disposed at the remaining area except for the bending area BA, but embodiments of the present disclosure are not limited thereto. The third insulating layer 115c may be disposed at the display area AA, the first non-display area NA1, and the second non-display area NA2. At least a portion of the third insulating layer 115c in the bending area BA may be removed. The third insulating layer 115c may be composed of an organic insulating material, but embodiments of the present disclosure are not limited thereto. For example, the third insulating layer 115c may be composed of a photo resist, polyimide (PI), or photo acryl-based material, or the like, but embodiments of the present disclosure are not limited thereto.

A plurality of banks BNK may be disposed on the third insulating layer 115c in the display area AA. The plurality of banks BNK may be disposed to overlap each of the plurality of sub-pixels. The plurality of banks BNK may not be disposed in the first non-display area NA1, the second non-display area NA2, and the bending area BA. One or more light emitting devices ED of a same type may be disposed on each of the plurality of banks BNK.

A plurality of signal lines TL may be disposed on the third insulating layer 115c in the display area AA. The plurality of signal lines TL may be disposed at an area between the plurality of banks BNK. For example, the plurality of signal lines TL may be disposed adjacent to any one of the plurality of banks BNK. Each of the plurality of signal lines TL may be electrically connected to the first connection line 121, for example, the 1-4^{th} connection line 121d.

A plurality of contact electrodes CCE may be disposed on the third insulating layer 115c in the display area AA. The plurality of contact electrodes CCE may supply a cathode voltage from the pixel driving circuit PD to the second electrode CE2. Each of the plurality of contact electrodes CCE may be electrically connected to the first connection line 121, for example, the 1-4^{th} connection line 121d.

The first electrode CE1 may be disposed on the bank BNK. For example, the first electrode CE1 may be disposed to extend from adjacent signal line TL toward an upper portion of the bank BNK. The first electrode CE1 may be disposed on an upper surface of the bank BNK and a side surface of the bank BNK. For example, the first electrode CE1 may be disposed to extend from the signal line TL on the third insulating layer 115c to the side surface of the bank BNK and the upper surface of the bank BNK. The first electrode CE1 may be a contact electrode. The first electrode CE1 may be formed integrally with the signal line TL.

Referring to FIG. 9, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, each of the first conductive layer CE1a, the second conductive layer CE1b, the third conductive layer CE1c, and the fourth conductive layer CE1d may be composed of titanium (Ti), molybdenum (Mo), aluminum (Al), or titanium (Ti) and indium tin oxide (ITO), but embodiments of the present disclosure are not limited thereto.

According to an embodiment of the present disclosure, some of the conductive layers having high reflection efficiency, among the plurality of conductive layers configuring the first electrode CE1, may be configured as an alignment key and/or a reflective plate (or reflector) for aligning the light emitting device ED. For example, the second conductive layer CE1b among the plurality of conductive layers configuring the first electrode CE1 may include a reflective material. For example, the second conductive layer CE1b may include aluminum (Al), but embodiments of the present disclosure are not limited thereto. Accordingly, the second conductive layer CE1b may be configured as the reflective plate. In addition, due to the high reflection efficiency of the second conductive layer CE1b, it may be easy to identify in a manufacturing process, and thus, a position or a transfer position of the light emitting device ED may be aligned based on the second conductive layer CE1b.

According to an embodiment of the present disclosure, in order to configure the second conductive layer CE1b as the reflective plate, the third conductive layer CE1c and the fourth conductive layer CE1d covering the second conductive layer CE1b may be partially removed or etched. For example, a portion of the third conductive layer CE1c and the fourth conductive layer CE1d disposed on the bank BNK may be removed or etched, thereby exposing an upper surface of the second conductive layer CE1b. For example, a center portion and a border portion (or an edge portion) of the third conductive layer CE1c and the fourth conductive layer CE1d, where the solder pattern SDP is disposed, may not be removed, and the remaining portions other than these may be removed. For example, the border portion (or edge portion) and the center portion of each of the third conductive layer CE1c which is made of titanium (Ti) and the fourth conductive layer CE1d which is made of indium tin oxide (ITO) may not be removed or etched. Accordingly, corrosion of other conductive layers configuring the first electrode CE1 may be prevented or minimized by an etchant (for example, a TMAH (Tetramethylammonium Hydroxide) solution) used in a mask process (or patterning process) of the first electrode CE1.

According to an embodiment of the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has good adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but embodiments of the present disclosure are not limited thereto.

As can be seen in FIGS. 8 and 9, according to an embodiment of the present disclosure, the signal line TL, the contact electrode CCE, and the pad electrode PE disposed at a same layer as the first electrode CE1 may be configured with a multilayer structure of a conductive material, but embodiments of the present disclosure are not limited thereto. For example, the signal line TL, the contact electrode CCE, and the pad electrode PE may be configured with a multilayer structure of indium tin oxide (ITO)/titanium (Ti)/aluminum (Al)/titanium (Ti), but embodiments of the present disclosure are not limited thereto.

According to an embodiment of the present disclosure, the solder pattern SDP may be disposed on the first electrode CE1 in each of the plurality of sub-pixels. The solder pattern SDP may bond the light emitting device ED to the first electrode CE1. The first electrode CE1 and the light emitting device ED may be electrically connected through eutectic bonding using the solder pattern SDP, but embodiments of the present disclosure are not limited thereto. For example, when the solder pattern SDP is made of indium (In) and the anode electrode 134 of the light emitting device ED is made of gold (Au), the solder pattern SDP and the anode electrode 134 may be bonded by applying heat and pressure in a transfer process of the light emitting device ED. The light emitting device ED may be bonded to the solder pattern SDP and the first electrode CE1 through eutectic bonding without a separate adhesive. For example, the solder pattern SDP may be composed of indium (In), tin (Sn), or an alloy thereof, but embodiments of the present disclosure are not limited thereto. For example, the solder pattern SDP may be a contact pattern, a bonding pad, or a joining pad, or the like, but embodiments of the present disclosure are not limited thereto.

According to an embodiment of the present disclosure, a passivation layer 116 may be disposed on the wiring layer. For example, the passivation layer 116 may be configured to cover the wiring layer in the display area AA. For example, the passivation layer 116 may be disposed on the plurality of signal lines TL, the plurality of first electrodes CE1, the plurality of contact electrodes CCE, and the third insulating layer 115c. For example, the passivation layer 116 may be disposed at the display area AA, the first non-display area NA1, and the second non-display area NA2. At least a portion of the passivation layer 116 disposed at the bending area BA may be removed. A portion of the passivation layer 116 covering the plurality of pad electrodes PE in the second non-display area NA2 may be removed. A portion of the passivation layer 116 covering the plurality of contact electrodes CCE in the display area AA may be removed. The passivation layer 116 covering the solder pattern SDP in the display area AA may be removed. The passivation layer 116 may cover the first electrode CE1. The passivation layer 116 may cover a portion of the upper surface of the exposed second conductive layer CE1b.

The passivation layer 116 is disposed to expose at least a portion of the plurality of pad electrodes PE, the plurality of contact electrodes CCE, and the solder pattern SDP while covering the remaining area, so as to reduce the penetration of moisture or impurities into the light emitting device ED. For example, the passivation layer 116 may be composed of a single layer or multiple layers of silicon oxide (SiOx) or silicon nitride (SiNx), but embodiments of the present disclosure are not limited thereto. For example, the passivation layer 116 may be a protective layer, an organic insulating layer, or an inorganic insulating layer, or the like, but embodiments of the present disclosure are not limited thereto. For example, the passivation layer 116 may include a hole exposing the solder pattern SDP and a hole exposing the contact electrode CCE.

In each of the plurality of sub-pixels, the light emitting device ED may be disposed on the solder pattern SDP. A first light emitting device 130 may be disposed in a first sub-pixel SP1. A second light emitting device 140 may be disposed in a second sub-pixel SP2. A third light emitting device 150 may be disposed in a third sub-pixel SP3.

The light emitting device ED may be formed on a silicon wafer by a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, or the like, but embodiments of the present disclosure are not limited thereto.

Referring to FIG. 9, the first light emitting device 130 may include an anode electrode 134, a first semiconductor layer 131, an active layer 132, a second semiconductor layer 133, a cathode electrode 135, and an encapsulation film 136, but embodiments of the present disclosure are not limited thereto. For example, the encapsulation film 136 may not be included in the first light emitting device 130.

The first semiconductor layer 131 may be disposed on a solder pattern SDP. The second semiconductor layer 133 may be disposed on the first semiconductor layer 131.

According to an embodiment of the present disclosure, one of the first semiconductor layer 131 and the second semiconductor layer 133 may be implemented as a compound semiconductor of a group III-V or a group II-VI, or the like, and may be doped with an impurity (or dopant). For example, one of the first semiconductor layer 131 and the second semiconductor layer 133 may be a semiconductor layer doped with an n-type impurity, and the other may be a semiconductor layer doped with a p-type impurity, but embodiments of the present disclosure are not limited thereto. For example, one or more of the first semiconductor layer 131 and the second semiconductor layer 133 may be a layer doped with an n-type or p-type impurity in a material such as gallium nitride (GaN), gallium phosphide (GaP), gallium arsenide phosphide (GaAsP), aluminum gallium indium phosphide (AlGaInP), indium aluminum phosphide (InAIP), aluminum gallium nitride (AlGaN), aluminum indium nitride (AlInN), aluminum indium gallium nitride (AlInGaN), aluminum gallium arsenide (AlGaAs), or gallium arsenide (GaAs), or the like, but embodiments of the present disclosure are not limited thereto. For example, the n-type impurity may be silicon (Si), germanium (Ge), selenium (Se), carbon (C), tellurium (Te), or tin (Sn), or the like, but embodiments of the present disclosure are not limited thereto. For example, the p-type impurity may be magnesium (Mg), zinc (Zn), calcium (Ca), strontium (Sr), barium (Ba), or beryllium (Be), or the like, but embodiments of the present disclosure are not limited thereto.

According to an embodiment of the present disclosure, the first semiconductor layer 131 and the second semiconductor layer 133 may be a nitride semiconductor including the n-type impurity and a nitride semiconductor including the p-type impurity, respectively, but embodiments of the present disclosure are not limited thereto. For example, the first semiconductor layer 131 may be a nitride semiconductor including the p-type impurity, and the second semiconductor layer 133 may be a nitride semiconductor including the n-type impurity, but embodiments of the present disclosure are not limited thereto.

The active layer 132 may be disposed (or interposed) between the first semiconductor layer 131 and the second semiconductor layer 133. The active layer 132 may receive holes and electrons from the first semiconductor layer 131 and the second semiconductor layer 133 to emit light. For example, the active layer 132 may be configured as one of a single well structure, a multi-well structure, a single quantum well structure, a multi-quantum well (MQW) structure, a quantum dot structure, and a quantum line structure, but embodiments of the present disclosure are not limited thereto. For example, the active layer 132 may be configured as indium gallium nitride (InGaN) or gallium nitride (GaN), or the like, but embodiments of the present disclosure are not limited thereto.

According to another embodiment of the present disclosure, the active layer 132 may include a multi-quantum well (MQW) structure having a well layer and a barrier layer having a higher band gap than the well layer. For example, the active layer 132 may include an indium gallium nitride (InGaN) layer as a well layer and an aluminum gallium nitride (AlGaN) layer as a barrier layer, but embodiments of the present disclosure are not limited thereto.

The anode electrode 134 may be disposed (or interposed) between the first semiconductor layer 131 and the solder pattern SDP. For example, the anode electrode 134 may be configured to electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be composed of a conductive material capable of eutectic bonding with the solder pattern SDP, but embodiments of the present disclosure are not limited thereto. For example, the anode electrode 134 may be composed of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or alloys thereof, or the like, but embodiments of the present disclosure are not limited thereto.

The cathode electrode 135 may be disposed on the second semiconductor layer 133. For example, the cathode electrode 135 may be configured to electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be composed of a transparent conductive material so that light emitted from the light emitting device ED may be directed toward an upper portion of the light emitting device ED, but embodiments of the present disclosure are not limited thereto. For example, the cathode electrode 135 may be composed of a material such as indium tin oxide (ITO), indium zinc oxide (IZO), or indium gallium zinc oxide (IGZO), or the like, but embodiments of the present disclosure are not limited thereto.

The encapsulation film 136 may be disposed on at least a portion of the first semiconductor layer 131, the active layer 132, the second semiconductor layer 133, the anode electrode 134, and the cathode electrode 135. For example, the encapsulation film 136 may surround at least a portion of the first semiconductor layer 131, the active layer 132, the second semiconductor layer 133, the anode electrode 134, and the cathode electrode 135.

The encapsulation film 136 may protect the first semiconductor layer 131, the active layer 132, and the second semiconductor layer 133. For example, the encapsulation film 136 may be disposed on side surfaces (or lateral surface) of the first semiconductor layer 131, side surfaces (or lateral surface) of the active layer 132, and side surfaces (or lateral surface) of the second semiconductor layer 133.

The encapsulation film 136 may be disposed on at least a portion of the anode electrode 134 and the cathode electrode 135 (for example, an edge portion (or a periphery portion or one side) of the anode electrode 134 and an edge portion (or a periphery portion or one side) of the cathode electrode 135). At least a portion of the anode electrode 134 that is not covered by the encapsulation film 136 may be exposed so that the anode electrode 134 and the solder pattern SDP may be connected. For example, at least a portion of the cathode electrode 135 that is not covered by the encapsulation film 136 may be exposed so that the cathode electrode 135 and the second electrode CE2 may be connected. For example, the encapsulation film 136 may be made of an insulating material such as silicon nitride (SiNx) or silicon oxide (SiOx), but embodiments of the present disclosure are not limited thereto.

According to another embodiment of the present disclosure, the encapsulation film 136 may have a structure in which a reflective material is dispersed in a resin layer, but embodiments of the present disclosure are not limited thereto. For example, the encapsulation film 136 may be manufactured as a reflector of various structures, but embodiments of the present disclosure are not limited thereto. Light emitted from the active layer 132 may be reflected upward by the encapsulation film 136, thereby improving light extraction efficiency. For example, the encapsulation film 136 may be a reflective layer, but embodiments of the present disclosure are not limited thereto.

According to an embodiment of the present disclosure, the light emitting device ED has been described as having a vertical structure, but embodiments of the present disclosure are not limited thereto. For example, the light emitting device ED may have a lateral structure or a flip chip structure.

Although the first light emitting device 130 has been described with reference to FIG. 9, the second light emitting device 140 and the third light emitting device 150 may have substantially a same structure as the first light emitting device 130. For example, the second light emitting device 140 and the third light emitting device 150 include substantially a same configuration as the first semiconductor layer 131, the active layer 132, the second semiconductor layer 133, the anode electrode 134, the cathode electrode 135, and the encapsulation film 136 of the first light emitting device 130, and therefore, their repetitive descriptions may be omitted.

As can be seen in FIGS. 8 and 9, the display apparatus 1000 according to an embodiment of the present disclosure may further include an optical layer (or light diffusion layer) 117a, 117b, and 117c.

The optical layers 117a, 117b, and 117c may be configured to surround a plurality of light emitting devices ED in the display area AA. For example, the optical layers 117a, 117b, and 117c may be configured to cover the plurality of light emitting devices ED in the display area AA. For example, the optical layers 117a and 117b may be configured over the insulating layer 115 to surround side surfaces of each of the plurality of light emitting devices ED and the side surfaces of each of the plurality of banks BNK.

According to an embodiment of the present disclosure, a first optical layer 117a may be disposed to surround the plurality of light emitting devices ED in the display area AA. For example, the first optical layer 117a may be disposed to cover side surfaces of the plurality of light emitting devices ED and side surfaces of the plurality of banks BNK in areas of the plurality of sub-pixels. For example, the first optical layer 117a may cover a portion of the passivation layer 116. For example, the first optical layer 117a may cover the second electrode CE2, the portion of the passivation layer 116, and between the plurality of light emitting devices ED. The first optical layer 117a may be disposed or cover between the plurality of light emitting devices ED included in one pixel PX and between the plurality of banks BNK. For example, the first optical layer 117a may extend along a row direction of the display area AA, and the plurality of first optical layers 117a may be spaced apart along a column direction (or the second direction Y) of the display area AA. For example, the first optical layer 117a may be disposed to surround side portions of each of the plurality of light emitting devices ED and the plurality of banks BNK between the insulating layer 115 and the second electrode CE2. For example, the first optical layer 117a may be disposed to surround side portions of each of the light emitting devices ED and the banks BNK between the passivation layer 116 and the second electrode CE2, but embodiments of the present disclosure are not limited thereto. For example, the first optical layer 117a may be a diffusion layer or a sidewall diffusion layer, but embodiments of the present disclosure are not limited thereto.

The first optical layer 117a may include an organic insulating material having fine particles 117ap dispersed therein, but embodiments of the present disclosure are not limited thereto. For example, the first optical layer 117a may be composed of siloxane having fine metal particles 117ap, such as titanium dioxide (TiO₂) particles, dispersed therein, but embodiments of the present disclosure are not limited thereto. Light from a plurality of light emitting devices ED may be scattered by the fine particles 117ap dispersed in the first optical layer 117a and emitted to an outside of the display panel 100. Accordingly, the first optical layer 117a may improve the extraction efficiency of light emitted from the plurality of light emitting devices ED.

According to an embodiment of the present disclosure, the first optical layer 117a may be disposed at each of the plurality of pixels PX or may be disposed together at some of the pixels PX which are disposed in a same row of the display area AA, but embodiments of the present disclosure are not limited thereto. For example, the first optical layer 117a may be disposed at each of the plurality of pixels PX or one first optical layer 117a may be disposed to share the plurality of pixels PX. As another embodiment of the present disclosure, each of the plurality of sub-pixels may separately include the first optical layer 117a, but embodiments of the present disclosure are not limited thereto.

According to an embodiment of the present disclosure, a second optical layer 117b may be disposed on the passivation layer 116 in the display area AA. For example, the second optical layer 117b may be disposed to surround side portions of the first optical layer 117a. For example, the second optical layer 117b may be in contact with side surfaces of the first optical layer 117a. For example, the second optical layer 117b may be disposed at an area (or a non-emitting area) between a plurality of pixels PX, but embodiments of the present disclosure are not limited thereto. For example, the second optical layer 117b may be a diffusion layer, a diffusion layer window, or a window diffusion layer, or the like, but embodiments of the present disclosure are not limited thereto.

The second optical layer 117b may be composed of an organic insulating material, but embodiments of the present disclosure are not limited thereto. The second optical layer 117b may be composed of a same material as the first optical layer 117a, but embodiments of the present disclosure are not limited thereto. For example, the first optical layer 117a may include fine particles, and the second optical layer 117b may not include the fine particles. For example, the second optical layer 117b may be composed of siloxane, but embodiments of the present disclosure are not limited thereto.

According to an embodiment of the present disclosure, a thickness of the first optical layer 117a may be smaller than a thickness of the second optical layer 117b, but embodiments of the present disclosure are not limited thereto. For example, an upper surface of the second optical layer 117b may be formed as a flat surface, and an upper surface of the first optical layer 117a may be formed as a concave curved surface. Accordingly, when viewed in a plan view, an area where the first optical layer 117a is disposed may include a concave portion which is recessed inwardly more than the upper surface of the second optical layer 117b.

According to an embodiment of the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of light emitting devices ED. For example, the second electrode CE2 may include a transparent conductive oxide such as indium tin oxide (ITO) or indium zinc oxide (IZO), or the like, but embodiments of the present disclosure are not limited thereto. For example, the second electrode CE2 may be disposed to be in contact with or directly in contact with the cathode electrode 135. For example, the second electrode CE2 may overlap an entire of the first optical layer 117a and may overlap a portion of the second optical layer 117b. For example, the second electrode CE2 may be electrically connected to the contact electrode CCE through the second optical layer 117b. For example, the second electrode CE2 may be electrically connected to the contact electrode CCE through the contact hole formed in the second optical layer 117b.

The second electrode CE2 may be continuously extended along the row direction (or the first direction X) of the substrate 110. Accordingly, the second electrode CE2 may be commonly connected to the plurality of light emitting devices ED in each of the plurality of pixels PX arranged along the row direction (or the first direction X) of the substrate 110.

According to an embodiment of the present disclosure, the second electrode CE2 may extend continuously over the first optical layer 117a, the second optical layer 117b, and the light emitting device ED. A region where the first optical layer 117a is disposed may include a concave portion which is recessed inwardly more than the upper surface of the second optical layer 117b. Accordingly, a first portion of the second electrode CE2 disposed on the first optical layer 117a may be disposed along the concave portion, and thus may be disposed at a lower position than a second portion of the second electrode CE2 disposed on the second optical layer 117b. For example, the thickness of the first optical layer 117a may progressively decrease from the second optical layer 117b toward a center of the first optical layer 117a for electrical connection (or contact) between each of the first to third light emitting devices 130, 140, and 150 and the second electrode CE2.

The third optical layer 117c may be disposed on the second electrode CE2. The third optical layer 117c may be disposed on the second electrode CE2 so as to overlap with the plurality of light emitting devices ED and the first optical layer 117a. For example, the third optical layer 117c may be disposed so as not to overlap with the second optical layer 117b. Since the third optical layer 117c is disposed on the second electrode CE2 and the plurality of light emitting devices ED, it is possible to improve a stain Mura that may occur in some of the plurality of light emitting devices ED. For example, when transferring the plurality of light emitting devices ED onto the substrate 110 of the display panel 100, an area in which an interval (or a spacing) between the plurality of light emitting devices ED is not uniform may occur due to process deviation, or the like. When the interval between the plurality of light emitting devices ED is non-uniform, an emission area of each of the plurality of light emitting devices ED may be non-uniformly formed, and thus, a Mura may be visually recognized by the user. Accordingly, since the third optical layer 117c for uniformly diffusing light is additionally configured on an upper portion of the plurality of light emitting devices ED, the light emitted from some of the light emitting devices ED may be reduced or prevented from being visually recognized as the Mura. Therefore, since the light emitted from the plurality of light emitting devices ED is uniformly diffused by the third optical layer 117c and extracted to the outside of the display panel 100, uniformity of luminance of the display apparatus may be improved.

The third optical layer 117c may be composed of an organic insulating material having fine particles 117cp dispersed therein, but embodiments of the present disclosure are not limited thereto. For example, the third optical layer 117c may be composed of siloxane having fine metal particles 117cp such as titanium dioxide (TiO₂) particles dispersed therein, but embodiments of the present disclosure are not limited thereto. For example, the third optical layer 117c may be composed of a same material as the first optical layer 117a, but embodiments of the present disclosure are not limited thereto. For example, the third optical layer 117c may be a diffusion layer or a top diffusion layer, but embodiments of the present disclosure are not limited thereto.

According to an embodiment of the present disclosure, light from a plurality of light emitting devices ED may be scattered by fine particles 117cp dispersed in the third optical layer 117c and emitted to the outside of the display panel 100. The third optical layer 117c may uniformly mix (or diffuse) light emitted from the plurality of light emitting devices ED, thereby further improving uniformity of luminance of the display apparatus. In addition, light extraction efficiency of the display apparatus may be improved by the light scattered by the fine particles 117cp, and thus the display apparatus may be driven at a low-power.

In the display area AA, a black matrix BM may be disposed on the second electrode CE2, the first optical layer 117a, the second optical layer 117b, and the third optical layer 117c. For example, the black matrix BM may fill the contact hole of the second optical layer 117b. Since the black matrix BM is configured to cover the display area AA, color mixing of light and external light reflection of the plurality of sub-pixels may be reduced. For example, the black matrix BM may also be disposed within the contact hole where the second electrode CE2 and the contact electrode CCE are connected, light leakage between the plurality of adjacent sub-pixels may be prevented. For example, the black matrix BM may be made of an opaque material, but embodiments of the present disclosure are not limited thereto. For example, the black matrix BM may be an organic insulating material to which a black pigment or a black dye is added, but embodiments of the present disclosure are not limited thereto.

Referring to FIG. 8, the display apparatus 1000 according to an embodiment of the present disclosure may further include a cover layer 118.

The cover layer 118 may be configured to cover the display area AA. For example, the cover layer 118 may be disposed on the black matrix BM in the display area AA. The cover layer 118 may be configured to protect the plurality of light emitting devices ED. For example, the components configured between the substrate 110 and the cover layer 118 may be protected by the substrate 110 and the cover layer 118. For example, the cover layer 118 may be configured of an organic insulating material, but embodiments of the present disclosure are not limited thereto. For example, the cover layer 118 may be configured of a photo resist, a polyimide (PI), or a photo acryl-based material, but embodiments of the present disclosure are not limited thereto. For example, the cover layer 118 may be an overcoating layer or an insulating layer, but embodiments of the present disclosure are not limited thereto.

A polarizing layer 180 may be disposed on the cover layer 118 by using a first adhesive layer 181. A cover member 120 may be disposed on the polarizing layer 180 by using a second adhesive layer 185. For example, a touch panel 200 may be disposed (or interposed) between the polarizing layer 180 and the second adhesive layer 185. The polarizing layer 180 may be connected (or attached) to a rear surface of the touch panel 200 by using a third adhesive layer 187. The touch panel 200 may be connected (or attached) to a rear surface of the cover member 120 by using the second adhesive layer 185. For example, each of the first adhesive layer 181, the second adhesive layer 185, and the third adhesive layer 187 may include an optically cleared adhesive (OCA), an optically cleared resin (OCR), or a pressure sensitive adhesive (PSA), but embodiments of the present disclosure are not limited thereto.

According to an embodiment of the present disclosure, a plurality of pad electrodes PE may be disposed on a third insulating layer 115c in the second non-display area NA2. For example, at least a portion of the plurality of pad electrodes PE may be exposed without being covered by the passivation layer 116. For example, the plurality of pad electrodes PE may be electrically connected to the 2-4^{th} connection line 122d through a contact hole of the third insulating layer 115c.

An adhesive film ACF may be disposed on the plurality of pad electrodes PE. The adhesive film ACF may be an adhesive layer in which conductive balls are dispersed on an insulating material, but embodiments of the present disclosure are not limited thereto. When heat and/or pressure is applied to the adhesive film ACF, the conductive balls may be electrically connected at a portion where the heat and/or pressure is applied, thereby having conductive characteristics. By disposing the adhesive film ACF between the plurality of pad electrodes PE and the flexible circuit board (or flexible film) 310, the flexible circuit board (or flexible film) 310 may be attached or bonded to the plurality of pad electrodes PE. For example, the adhesive film ACF may be a conductive adhesive material, a conductive adhesive film, or an anisotropic conductive film, but embodiments of the present disclosure are not limited thereto.

A flexible circuit board (or flexible film) 310 may be placed on an adhesive film ACF. The flexible circuit board (or flexible film) 310 may be electrically connected to a plurality of pad electrodes PE through the adhesive film ACF. Accordingly, signals output from the flexible circuit board (or flexible film) 310 and the printed circuit board 330 may be transmitted to the pixel driving circuit PD in the display area AA through a wiring layer. For example, signals output from the printed circuit board 330 may be transmitted to the pixel driving circuit PD in the display area AA through the flexible circuit board 310, the plurality of pad electrodes PE, the 2-4^{th} connection line 122d, the 2-3^{th} connection line 122c, the 2-2th connection line 122b, and the 2-1^{th} connection line 122a.

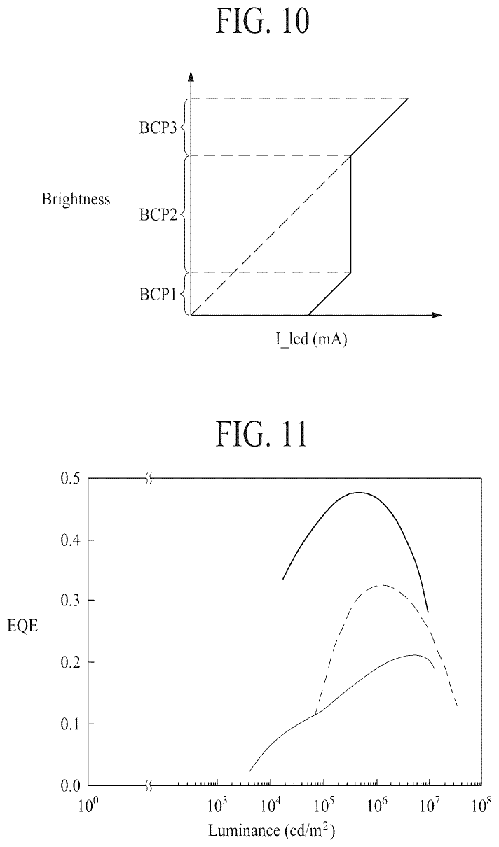

FIG. 10 is a diagram illustrating brightness based on current flowing through a light emitting device according to an embodiment of the present disclosure. FIG. 11 illustrates an external quantum efficiency EQE of each of a red emitting device, a green emitting device, and a blue light emitting device according to an embodiment of the present disclosure.

Referring to FIGS. 10 and 11, in the display apparatus according to an embodiment of the present disclosure, the external quantum efficiency of each of a red light emitting device, a green light emitting device, and a blue light emitting device are different depending on luminance. For example, the external quantum efficiency of the light emitting device with respect to luminance may be the highest for the blue of the thick solid line, the lowest for the red of the solid line, and the green of the dotted line may be lower than blue and higher than red. Accordingly, when the light emitting device is driven (or emitted light) by linearly setting the brightness with respect to the current I_led, as in the dotted line illustrated in FIG. 10, a low efficiency region may occur depending on the external quantum efficiency of each of the red light emitting device, the green light emitting device, and the blue light emitting device, and power consumption may increase due to the low efficiency region.

According to an embodiment of the present disclosure, the brightness of the plurality of light emitting devices may include first to third brightness regions BCP1, BCP2, and BCP3. For example, the brightness of the plurality of light emitting devices may include first to third brightness regions BCP1, BCP2, and BCP3 between a minimum brightness and a maximum brightness. For example, the brightness of each of the red light emitting device, the green light emitting device, and the blue light emitting device may include first to third brightness regions BCP1, BCP2, and BCP3. For example, the brightness range for the current I_led can include first to third brightness regions BCP1, BCP2, and BCP3 based on external quantum efficiency of each of the red light emitting device, the green light emitting device, and the blue light emitting device for luminance. For example, the brightness of each of the red light emitting device, the green light emitting device, and the blue light emitting device may include first to third brightness regions BCP1, BCP2, and BCP3.

The first brightness region BCP1 may be a low brightness region including a minimum brightness in the brightness range. The third brightness region BCP3 may be a high brightness region higher than the second brightness region BCP2 including a maximum brightness in the brightness range. The second brightness region BCP2 may be a medium brightness region between the first brightness region BCP1 and the third brightness region BCP3 in the brightness range. For example, the first to third brightness regions BCP1, BCP2, and BCP3 may be individually set for each of the red light emitting device, the green light emitting device, and the blue light emitting device. For example, the first to third brightness regions BCP1, BCP2, and BCP3 of each of the red light emitting device, the green light emitting device, and the blue light emitting device may be different from each other.

In the display apparatus according to an embodiment of the present disclosure, the light emitting device may be driven (or emitted light) in a pulse amplitude modulation method or a pulse width modulation method based on the first to third brightness regions BCP1, BCP2, and BCP3. For example, the light emitting device may be driven (or emitted light) in the pulse amplitude modulation method based on a reference voltage and an emission signal in the first brightness region BCP1 and the third brightness region BCP3, and may be driven (or emitted light) in the pulse width modulation method based on the reference voltage and the emission signal in the second brightness region BCP2.

In the first brightness region BCP1 based on the pulse amplitude modulation method, the on-period of the emission signal applied to the pixel driving circuit PD may be varied (or adjusted) to correspond to a grayscale value of the pixel data, and the reference voltage applied to the pixel driving circuit PD may be varied (or adjusted) based on a target brightness or a user-set brightness in the first brightness region BCP1. According to an embodiment of the present disclosure, the maximum on-period of the emission signal in the first brightness region BCP1 may correspond to a maximum grayscale value of the pixel data. For example, the maximum on-period of the emission signal in the first brightness region BCP1 may be 5 us microseconds, but embodiments of the present disclosure are not limited thereto. For example, the on-period of the emission signal corresponding to the grayscale value of the pixel data in the first brightness region BCP1 may be divided evenly or unequally within the maximum on-period. For example, in the first brightness region BCP1, the reference voltage may have a lower voltage level as a screen brightness corresponding to the target brightness or the user-set brightness is higher. For example, in the first brightness region BCP1, the absolute value of the reference voltage may be larger as the screen brightness corresponding to the target brightness or the user-set brightness is higher.

In the second brightness region BCP2 based on the pulse width modulation method, the on-period of the emission signal applied to the pixel driving circuit PD may be varied (or adjusted) to correspond to the grayscale value of the pixel data, and the reference voltage applied to the pixel driving circuit PD may be fixed. According to an embodiment of the present disclosure, the maximum on-period of the emission signal in the second brightness region BCP2 may correspond to the maximum grayscale value of the pixel data. For example, the minimum on-period of the emission signal in the second brightness region BCP2 may be 5 μs, and the maximum on-period of the emission signal may be 1000 μs, but embodiments of the present disclosure are not limited thereto. For example, the on-period of the emission signal corresponding to the grayscale value of the pixel data in the second brightness region BCP2 may be evenly or unequally divided between the minimum on-period and the maximum on-period. For example, in the second brightness region BCP2, the reference voltage may have a predetermined fixed voltage level regardless of the target brightness or the user-set brightness.

In the third brightness region BCP3 based on the pulse amplitude modulation method, the on-period of the emission signal applied to the pixel driving circuit PD is varied (or adjusted) to correspond to the grayscale value of the pixel data, and the reference voltage applied to the pixel driving circuit PD may be varied (or adjusted) based on the target brightness or the user-set brightness in the third brightness region BCP3. According to an embodiment of the present disclosure, the maximum on-period of the emission signal in the third brightness region BCP3 may correspond to the maximum grayscale value of the pixel data. For example, the maximum on-period of the emission signal in the third brightness region BCP3 may be 1000 us microseconds, but embodiments of the present disclosure are not limited thereto. For example, the on-period of the emission signal corresponding to the grayscale value of the pixel data in the third brightness region BCP3 may be divided evenly or unequally within the maximum on-period. For example, in the third brightness region BCP3, the reference voltage may have a lower voltage level as the screen brightness corresponding to the target brightness or the user-set brightness is higher. For example, in the third brightness region BCP3, the absolute value of the reference voltage may be larger as the screen brightness corresponding to the target brightness or the user-set brightness is higher.

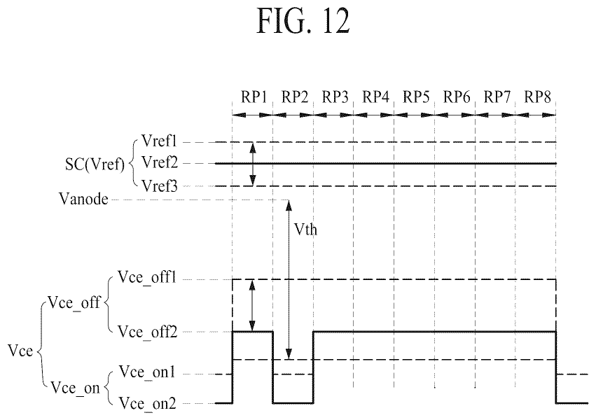

FIG. 12 illustrates a reference voltage and a cathode voltage in a display apparatus according to an embodiment of the present disclosure.

Referring to FIG. 12, in the display apparatus according to an embodiment of the present invention, the light emitting device may emit light by a cathode-on voltage Vce_on for each column driving period (or a horizontal period) RP1 to RP8, and may implement a grayscale corresponding to pixel data at a brightness corresponding to a reference voltage Vref.

The reference voltage Vref may be set based on the first to third brightness regions BCP1, BCP2, and BCP3 as described above with reference to FIG. 10. For example, the reference voltage Vref may include a plurality of reference voltages Vref1, Vref2, and Vref3. For example, the reference voltage Vref may include a first reference voltage Vref1 based on the first brightness region BCP1, a second reference voltage Vref2 based on the second brightness region BCP2, and a third reference voltage Vref3 based on the third brightness region BCP3, but embodiments of the present disclosure are not limited thereto.

The first reference voltage Vref1 may be varied (or adjusted) to correspond to the target brightness or the user-set brightness based on the pulse amplitude modulation method in the first brightness region BCP1, the second reference voltage Vref2 may have a fixed voltage level in the second brightness region BCP2, and the third reference voltage Vref3 may be varied (or adjusted) to correspond to the target brightness or the user-set brightness based on the pulse amplitude modulation method in the third brightness region BCP3. For example, the second reference voltage Vref_V2 may be a normal reference voltage or a fixed reference voltage.

The third reference voltage Vref3 may be lower than the second reference voltage Vref2, and the second reference voltage Vref2 may be lower than the first reference voltage Vref1. For example, the absolute value of the third reference voltage Vref3 may be greater than the absolute value of the second reference voltage Vref2, and the absolute value of the second reference voltage Vref2 may be greater than the absolute value of the first reference voltage Vref1.

Referring to FIGS. 10 and 12, the cathode voltage Vce may include a cathode-on voltage Vce_on and a cathode-off voltage Vce_off.

The cathode-on voltage Vce_on may have a voltage level for turning on the light emitting device or maintaining the light emitting device in an on state. The cathode-on voltage Vce_on may have a voltage level higher than a threshold voltage Vth of the light emitting device with respect to the reference voltage Vref or an anode voltage Vanode of the light emitting device. For example, a voltage difference (Vref-Vce_on) between the cathode-on voltage Vce_on and the reference voltage Vref may be greater than the threshold voltage Vth of the light emitting device. For example, an absolute value of the voltage difference (Vref-Vce_on) between the cathode-on voltage Vce_on and the reference voltage Vref may be greater than the absolute value of the threshold voltage Vth of the light emitting device. For example, the voltage difference (Vanode-Vce_on) between the anode voltage Vanode and the cathode-on voltage Vce_on of the light emitting device may be greater than the threshold voltage Vth of the light emitting device. For example, the absolute value of the voltage difference (Vanode-Vce_on) between the anode voltage Vanode and the cathode-on voltage Vce_on of the light emitting device may be greater than the absolute value of the threshold voltage Vth of the light emitting device. For example, the threshold voltage Vth of the light emitting device may have a voltage level that is greater than a voltage difference (Vanode-Vce_off) between the anode voltage Vanode and the cathode-off voltage Vce_off of the light emitting device and smaller than the voltage difference (Vanode-Vce_on) between the anode voltage Vanode and the cathode-on voltage Vce_on of the light emitting device, but embodiments of the present disclosure are not limited thereto.

According to an embodiment of the present disclosure, the cathode-on voltage Vce_on may have a same voltage level in the first to third brightness regions BCP1, BCP2, and BCP3, but embodiments of the present disclosure are not limited thereto. For example, the cathode-on voltage Vce_on may have different voltage levels in each of the first to third brightness regions BCP1, BCP2, and BCP3.

The cathode-off voltage Vce_off may have a voltage level for turning off the light emitting device or maintaining the light emitting device in the off state. The cathode-off voltage Vce_off may have a voltage level equal to or less than the threshold voltage Vth of the light emitting device with respect to a reference voltage Vref1, Vref2, and Vref3 or an anode voltage Vanode of the light emitting device. For example, the threshold voltage Vth of the light emitting device may have a voltage level between the cathode-off voltage Vce_off and the cathode-on voltage Vce_on. For example, a voltage difference (Vce_off-Vref) between the cathode-off voltage Vce_off and the reference voltages Vref1, Vref2, and Vref3 may be smaller than the threshold voltage Vth of the light emitting device. For example, the absolute value of the voltage difference (Vce_off-Vref) between the cathode-off voltage Vce_off and the reference voltages Vref1, Vref2, and Vref3 may be smaller than the absolute value of the threshold voltage Vth of the light emitting device. For example, a voltage difference (Vanode-Vce_off) between the anode voltage Vanode and the cathode-off voltage Vce_off of the light emitting device may be smaller than the threshold voltage Vth of the light emitting device. For example, the absolute value of the voltage difference (Vanode-Vce_off) between the anode voltage Vanode and the cathode-off voltage Vce_off of the light emitting device may be smaller than the absolute value of the threshold voltage Vth of the light emitting device.

According to an embodiment of the present disclosure, when each of the driving transistor TDR and the light-emitting transistor TEM of the micro-driver (uDriver) described above with reference to FIG. 4 is configured as a p-type transistor, the cathode-off voltage Vce_off may have a voltage level for preventing abnormal light emission of the light emitting device due to an abnormal voltage which is higher than a threshold voltage Vth of the light emitting device. For example, the cathode-off voltage Vce_off may have a voltage level relatively higher than the cathode-on voltage Vce_on. For example, the absolute value of the cathode-off voltage Vce_off may be smaller than the absolute value of the cathode-on voltage Vce_on. For example, the cathode-off voltage Vce_off may have a voltage level which is closer to the reference voltages Vref1, Vref2, and Vref3 (or the anode voltage of the light emitting device) than the cathode-on voltage Vce_on.

The cathode-off voltage Vce_off according to an embodiment of the present disclosure may be varied (or adjusted). For example, the cathode-off voltage Vce_off may be varied (or adjusted) based on the reference voltage Vref. For example, the cathode-off voltage Vce_off may be varied (or adjusted) to the voltage level which is closer to the cathode-on voltage Vce_on based on the reference voltage Vref.

The cathode-off voltage Vce_off according to an embodiment of the present disclosure may have a voltage level between the first cathode-off voltage Vce_off1 and the second cathode-off voltage Vce_off2. For example, the cathode-off voltage Vce_off may have the voltage level between the first cathode-off voltage Vce_off1 and the second cathode-off voltage Vce_off2 based on the reference voltage Vref. For example, the cathode-off voltage Vce_off may have a voltage level between the first cathode-off voltage Vce_off1 which is closer to the anode voltage Vanode of the light emitting device and the second cathode-off voltage Vce_off2 which is closer to the threshold voltage Vth of the light emitting device.

The first cathode-off voltage Vce_off1 may have a voltage level which is higher than the cathode-on voltage Vce_on. For example, the absolute value of the first cathode-off voltage Vce_off1 may be smaller than the absolute value of the cathode-on voltage Vce_on. For example, the first cathode-off voltage Vce_off1 may have a voltage level which is closer to the reference voltage Vref (or the anode voltage Vanode of the light emitting device) than the cathode-on voltage Vce_on. For example, the first cathode-off voltage Vce_off1 may have a higher voltage level than the cathode-on voltage Vce_on in order to prevent or at least reduce abnormal light emission of the light emitting device. For example, the first cathode-off voltage Vce_off1 may have a voltage level between the reference voltage Vref (or the anode voltage Vanode of the light emitting device) and the cathode-on voltage Vce_on. The first cathode-off voltage Vce_off1 may have a voltage level between the reference voltages Vref1, Vref2, and Vref3 (or the anode voltage Vanode of the light emitting device) and the threshold voltage Vth of the light emitting device. For example, the first cathode-off voltage Vce_off1 may be a cathode normal off voltage or a cathode reference off voltage.

The second cathode-off voltage Vce_off2 may have a voltage level which is lower than the first cathode-off voltage Vce_off1. For example, the absolute value of the second cathode-off voltage Vce_off2 may be greater than the absolute value of the first cathode-off voltage Vce_off1. For example, the second cathode-off voltage Vce_off2 may have a voltage level which is closer to the cathode-on voltage Vce_on than to the first cathode-off voltage Vce_off1. The second cathode-off voltage Vce_off2 may have a voltage level between the first cathode-off voltage Vce_off1 and the cathode-on voltage Vce_on in order to reduce power consumption of the display apparatus. For example, the second cathode-off voltage Vce_off2 may have a voltage level between the first cathode-off voltage Vce_off1 and the threshold voltage Vth of the light emitting device.

Referring to FIG. 12 as an example, in the display apparatus according to an embodiment of the present disclosure, the cathode-off voltage Vce_off may have the second cathode-off voltage Vce_off2. The cathode voltage Vce may be switched (or transitioned) between the cathode-on voltage Vce_on and the second cathode-off voltage Vce_off2 for each column driving period (or a horizontal period) RP1 to RP8. Accordingly, since a voltage swing width (or voltage transition width) between the cathode-on voltage Vce_on and the second cathode-off voltage Vce_off2 is reduced compared to a voltage swing width (or voltage transition width) between the cathode-on voltage Vce_on and the first cathode-off voltage Vce_off1, power consumption due to voltage switching (or voltage transition) may be reduced.

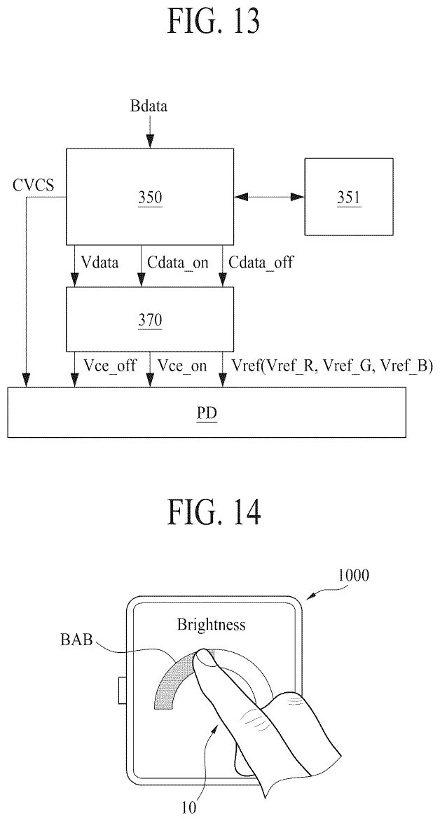

FIG. 13 illustrates a variable circuit for the reference voltage and the cathode voltage according to an embodiment of the present disclosure. FIG. 14 is a diagram illustrating screen brightness setting in a display apparatus according to an embodiment of the present disclosure.

Referring to FIGS. 13 and 14, in a display apparatus according to an embodiment of the present disclosure, a timing controller 350 may generate reference voltage data Vdata and cathode-off voltage data Cdata_off based on screen brightness data Bdata. The reference voltage data Vdata and cathode-off voltage data Cdata_off may be supplied to a pixel driving circuit PD.

The screen brightness data Bdata may correspond to the user's brightness selection (or setting). For example, the screen brightness data Bdata may be generated based on a finger touch by user 10 on a screen brightness control bar BAB displayed on the screen of the display apparatus 1000. For example, when the user 10 selects (or sets) an overall screen brightness (or a total screen brightness) of the screen through the finger touch on the screen brightness control bar BAB, the touch integrated circuit may generate touch raw data for the screen brightness based on a change in capacitance on the touch panel according to the finger touch of the user 10. Accordingly, the host control part may generate the screen brightness data Bdata based on the touch raw data for the screen brightness and supply the generated screen brightness data Bdata to the timing controller 350, but embodiments of the present disclosure are not limited thereto. For example, the timing controller 350 may generate the screen brightness data Bdata based on the touch raw data for the screen brightness.

The timing controller 350 may be configured to generate reference voltage data Vdata. For example, the timing controller 350 may generate the reference voltage data Vdata based on the screen brightness data Bdata. For example, the timing controller 350 may generate the reference voltage data Vdata including red reference voltage data, green reference voltage data, and blue reference voltage data based on the screen brightness data Bdata.

According to an embodiment of the present disclosure, the timing controller 350 may generate the reference voltage data Vdata based on a target brightness corresponding to the screen brightness data Bdata by using a look-up table stored in the memory 351. For example, in order to reduce a capacity of reference voltage data stored in the look-up table, the screen brightness of the display apparatus 1000 may be divided into a plurality of bands 1 to 14, and the reference voltage data (or brightness information) corresponding to each of the plurality of bands 1 to 14 may be stored in the look-up table. For example, the screen brightness of the display apparatus 1000 may be divided into the first to fourteenth bands 1 to 14 as illustrated in Table 1 below, but embodiments of the present disclosure are not limited thereto.

TABLE 1

| Band | Target nit | Vref_R | Vref_G | Vref_B |
|---|---|---|---|---|
| 14 | 1 | 1.15 | 1.30 | 1.21 |
| 13 | 2 | 1.12 | 1.26 | 1.16 |
| 12 | 4 | 1.09 | 1.21 | 1.10 |
| 11 | 6 | 1.05 | 1.21 | 1.03 |
| 10 | 14 | 0.93 | 1.21 | 1.03 |
| 9 | 23 | 0.82 | 1.21 | 1.03 |
| 8 | 39 | 0.68 | 1.21 | 1.03 |
| 7 | 86 | 0.68 | 1.21 | 1.03 |
| 6 | 132 | 0.68 | 1.21 | 1.03 |
| 5 | 288 | 0.68 | 1.21 | 1.03 |
| 4 | 400 | 0.68 | 1.13 | 1.03 |
| 3 | 800 | 0.68 | 0.97 | 0.87 |
| 2 | 1500 | 0.35 | 0.48 | 0.56 |
| 1 | 3000 | 0.12 | 0.05 | 0.30 |

In the lookup table, the target brightness of the first band 1 of the plurality of bands 1 to 14 may correspond to a maximum screen brightness of the display apparatus 1000. The fourteenth band 14 of the plurality of bands 1 to 14 may correspond to a minimum and maximum brightness of the display apparatus 1000.

Each of the red reference voltage Vref_R, the green reference voltage Vref_G, and the blue reference voltage Vref_B corresponding to the target brightness of each of the plurality of bands 1 to 14 may be individually set differently. For example, each of the red reference voltage Vref_R, the green reference voltage Vref_G, and the blue reference voltage Vref_B corresponding to the target brightness of each of the plurality of bands 1 to 14 may be set differently based on the external quantum efficiency of each of the red light emitting device, the green light emitting device, and the blue light emitting device illustrated in FIG. 11. Therefore, the luminous efficiency of each of the red light emitting device, the green light emitting device, and the blue light emitting device may be improved.

Referring to FIG. 10 and Table 1, the plurality of bands 1 to 14 may be divided into first to third brightness regions BCP1, BCP2, and BCP3. Each of the first to third brightness regions BCP1, BCP2, and BCP3 of the red light emitting device, the green light emitting device, and the blue light emitting device may include one or more different bands.

In the red reference voltage Vref_R stored in the look-up table according to an embodiment of the present disclosure, the first brightness region BCP1 may include the first and second bands 1 and 2, the second brightness region BCP2 may include the third to eighth bands 3 to 8, and the third brightness region BCP3 may include the ninth to fourteenth bands 9 to 14, but embodiments of the present disclosure are not limited thereto. For example, the red reference voltages Vref_R of each of the first and second bands 1 and 2 of the first brightness region BCP1 may be different for pulse amplitude modulation of the reference voltage Vref. The red reference voltages Vref_R of each of the third to eighth bands 3 to 8 of the second brightness region BCP2 may be a same for pulse width modulation of the reference voltage Vref. The red reference voltage Vref_R of each of the ninth to fourteenth bands 9 to 14 of the third brightness region BCP3 may be different for pulse amplitude modulation of the reference voltage Vref.

In the red reference voltage Vref_R stored in the look-up table according to an embodiment of the present disclosure, the red reference voltage Vref_R of the first brightness region BCP1 may have a voltage level of 0.12 V to 0.35 V based on a target brightness or a user-set brightness. The red reference voltage Vref_R of the second brightness region BCP2 may have a voltage level of 0.68 V regardless of the target brightness or the user-set brightness. The red reference voltage Vref_R of the third brightness region BCP3 may have a voltage level of 0.82 V to 1.15 V based on the target brightness or the user-set brightness. However, embodiments of the present disclosure are not limited thereto.

In the green reference voltage Vref_G stored in the look-up table according to an embodiment of the present disclosure, the first brightness region BCP1 may include the first to fourth bands 1 to 4, the second brightness region BCP2 may include the fifth to twelfth bands 5 to 12, and the third brightness region BCP3 may include the thirteenth and fourteenth bands 13 and 14, but embodiments of the present disclosure are not limited thereto. For example, the green reference voltages Vref_G of each of the first to fourth bands 1 to 4 of the first brightness region BCP1 may be different for pulse amplitude modulation of the reference voltage Vref. The green reference voltages Vref_G of each of the fifth to twelfth bands 5 to 12 of the second brightness region BCP2 may be a same for pulse width modulation of the reference voltage Vref. The green reference voltage Vref_G of each of the thirteenth and fourteenth bands 13 and 14 of the third brightness region BCP3 may be different for pulse amplitude modulation of the reference voltage Vref.

In the green reference voltage Vref_G stored in the look-up table according to an embodiment of the present disclosure, the green reference voltage Vref_G of the first brightness region BCP1 may have a voltage level of 0.05 V to 1.13 V based on the target brightness or the user-set brightness. The green reference voltage Vref_G of the second brightness region BCP2 may have a voltage level of 1.21 V regardless of the target brightness or the user-set brightness. The green reference voltage Vref_G of the third brightness region BCP3 may have a voltage level of 1.264 V to 1.30 V based on the target brightness or the user-set brightness. However, embodiments of the present disclosure are not limited thereto.

In the blue reference voltage Vref_B stored in the look-up table according to an embodiment of the present disclosure, the first brightness region BCP1 may include the first to third bands 1, 2, and 3, the second brightness region BCP2 may include the fourth to eleventh bands 4 to 11, and the third brightness region BCP3 may include the twelfth to fourteenth bands 12, 13, and 14, but embodiments of the present disclosure are not limited thereto. For example, the blue reference voltage Vref_B of each of the first to third bands 1, 2, and 3 of the first brightness region BCP1 may be different for pulse amplitude modulation of the reference voltage Vref. The blue reference voltages Vref_B of each of the fourth to eleventh bands 4 to 11 of the second brightness region BCP2 may be a same for pulse width modulation of the reference voltage Vref. The blue reference voltages Vref_B of each of the twelfth to fourteenth bands 12, 13, and 14 of the third brightness region BCP3 may be different for pulse amplitude modulation of the reference voltage Vref.

In the blue reference voltage Vref_B stored in the look-up table according to an embodiment of the present disclosure, the blue reference voltage Vref_B of the first brightness region BCP1 may have a voltage level of 0.30 V to 0.87 V based on the target brightness or the user-set brightness. The blue reference voltage Vref_B of the second brightness region BCP2 may have a voltage level of 1.03 V regardless of the target brightness or the user-set brightness. The blue reference voltage Vref_B of the third brightness region BCP3 may have a voltage level of 1.09 V to 1.21 V based on the target brightness or the user-set brightness. However, embodiments of the present disclosure are not limited thereto.

According to an embodiment of the present disclosure, the timing controller 350 may be configured to select a band 1 to 14 matching the target brightness corresponding to the screen brightness data Bdata among the plurality of bands 1 to 14 in the look-up table, extract the red reference voltage Vref_R, the green reference voltage Vref_G, and the blue reference voltage Vref_B corresponding to the selected band 1 to 14, and generate the reference voltage data Vdata including red reference voltage data, green reference voltage data, and blue reference voltage data corresponding to the extracted red reference voltage Vref_R, green reference voltage Vref_G, and blue reference voltage Vref_B, respectively.

According to an embodiment of the present disclosure, when the target brightness corresponding to the screen brightness data Bdata is a brightness between two adjacent bands among the plurality of bands 1 to 14, the timing controller 350 may be configured to calculate the red reference voltage Vref_R, the green reference voltage Vref_G, and the blue reference voltage Vref_B, respectively, by linear interpolation of reference voltages corresponding to the two adjacent bands, and generate the reference voltage data Vdata including red reference voltage data, green reference voltage data, and blue reference voltage data corresponding to the calculated red reference voltage Vref_R, green reference voltage Vref_G, and blue reference voltage Vref_B, respectively.

The timing controller 350 according to an embodiment of the present disclosure may be configured to generate cathode-off voltage data Cdata_off based on cathode-off voltage Vce_off corresponding to the screen brightness data Bdata in the look-up table stored in the memory 351. For example, the cathode-off voltage Vce_off for each band stored in the look-up table corresponding to each of the plurality of bands 1 to 14 may be applied to the light emitting device by applying the red reference voltage Vref_R, the green reference voltage Vref_G, and the blue reference voltage Vref_B for each of the plurality of bands 1 to 14, while the gate-off voltage Vce_off for each band is gradually varied (or adjusted), and a time of light emission when a difference voltage between the reference voltage Vref (or the anode voltage Vanode of the light emitting device) and the varied gate-off voltage Vce_off for each band exceeds the threshold voltage Vth of the light emitting device and the light emitting device abnormally emits light is measured, and may be the gate-off voltage Vce_off for each band at the stage immediately before the measured time of light emission.

According to an embodiment of the present disclosure, the gate-off voltage Vce_off corresponding to the first band 1 may correspond to the second cathode-off voltage Vce_off2. The gate-off voltage Vce_off corresponding to the fourteenth band 14 may correspond to the first cathode-off voltage Vce_off1. Accordingly, the gate-off voltage Vce_off for each band may have a voltage level between the first cathode-off voltage Vce_off1 and the second cathode-off voltage Vce_off2. However, embodiments of the present disclosure are not limited thereto.

According to an embodiment of the present disclosure, the timing controller 350 may be configured to select a band 1 to 14 matching the target brightness corresponding to the screen brightness data Bdata among the plurality of bands 1 to 14 in the look-up table, extract the cathode-off voltage Vce_off corresponding to the selected band 1 to 14, and generate the cathode-off voltage data Cdata_off corresponding to the extracted cathode-off voltage Vce_off.

According to an embodiment of the present disclosure, when the target brightness corresponding to the screen brightness data Bdata is a brightness between two adjacent bands among the plurality of bands 1 to 14, the timing controller 350 may be configured to calculate the cathode-off voltage Vce_off by linear interpolation of the cathode-off voltages Vce_off corresponding to each of the two adjacent bands, and generate cathode-off voltage data Cdata_off corresponding to the calculated cathode-off voltage Vce_off.

The timing controller 350 according to another embodiment of the present disclosure may be configured to vary (or adjust) the cathode-off voltage Vce_off according to the reference voltage Vref generated based on the screen brightness data Bdata. For example, the timing controller 350 may be configured to generate the cathode-off voltage data Cdata_off according to the reference voltage data Vdata generated based on the screen brightness data Bdata. For example, the timing controller 350 may be configured to vary (or adjust) the cathode-off voltage Vce_off according to the red reference voltage Vref_R, the green reference voltage Vref_G, and the blue reference voltage Vref_B generated based on the screen brightness data Bdata. For example, the timing controller 350 may be configured to generate the cathode-off voltage data Cdata_off for generating the cathode-off voltage Vce_off based on the red reference voltage data, the green reference voltage data, and the blue reference voltage data corresponding to the screen brightness data Bdata.

According to another embodiment of the present disclosure, the timing controller 350 may be configured to extract each of the red reference voltage Vref_R, the green reference voltage Vref_G, and the blue reference voltage Vref_B corresponding to the screen brightness data Bdata from the look-up table stored in the memory 351, and generate the cathode-off voltage data Cdata_off based on one or more of the red reference voltage data, the green reference voltage data, and the blue reference voltage data corresponding to each of the extracted red reference voltage Vref_R, the green reference voltage Vref_G, and the blue reference voltage Vref_B.

In another embodiment of the present disclosure, the timing controller 350 may generate the cathode-off voltage data Cdata_off based on a smallest value (or the smallest absolute value) among the red reference voltage data, the green reference voltage data, and the blue reference voltage data. In this case, since the voltage swing width (or voltage transition width) between the cathode-on voltage Vce_on and the cathode-off voltage Vce_off is reduced, power consumption according to voltage switching (or voltage transition) may be reduced, and abnormal light emission of the light emitting device may be prevented.

In another embodiment of the present disclosure, the timing controller 350 may generate the cathode-off voltage data Cdata_off based on an average value of the red reference voltage data, the green reference voltage data, and the blue reference voltage data. In this case, the voltage swing width (or voltage transition width) between the cathode-on voltage Vce_on and the cathode-off voltage Vce_off may be further reduced, and thus, the power consumption according to voltage switching (or voltage transition) may be further reduced and abnormal light emission of the light emitting device may be prevented.

In another embodiment of the present disclosure, the timing controller 350 may generate the cathode-off voltage data Cdata_off based on a largest value (or the largest absolute value) among the red reference voltage data, the green reference voltage data, and the blue reference voltage data. In this case, the voltage swing width (or voltage transition width) between the cathode-on voltage Vce_on and the cathode-off voltage Vce_off may be further reduced, and thus, the power consumption according to the voltage switching (or voltage transition) may be further reduced and abnormal light emission of the light emitting device may be prevented.

Referring to FIGS. 12 and 13, the cathode-on voltage Vce_on according to an embodiment of the present disclosure may be varied (or adjusted). For example, the cathode-on voltage Vce_on may be varied (or adjusted) based on the reference voltage Vref. For example, the cathode-on voltage Vce_on may be varied (or adjusted) to increase a brightness of a grayscale corresponding to the pixel data.

According to an embodiment of the present disclosure, the cathode-on voltage Vce_on may have a voltage level between the first cathode-on voltage Vce_on1 and the second cathode-on voltage Vce_on2. For example, the cathode-on voltage Vce_on may have a voltage level between the first cathode-on voltage Vce_on1 and the second cathode-on voltage Vce_on2 based on the reference voltage Vref.

The first cathode-on voltage Vce_on1 may have a voltage level which is higher than the threshold voltage Vth of the light emitting device. For example, an absolute value of the first cathode-on voltage Vce_on1 may be greater than an absolute value of the threshold voltage Vth of the light emitting device. For example, the first cathode-on voltage Vce_on1 may be a cathode normal on voltage or a cathode reference on voltage.

The second cathode-on voltage Vce_on2 may have a voltage level which is lower than the first cathode-on voltage Vce_on1. For example, the absolute value of the second cathode-on voltage Vce_on2 may be greater than the absolute value of the first cathode-on voltage Vce_on1.

The timing controller 350 according to another embodiment of the present disclosure may be configured to vary (or adjust) the cathode-on voltage Vce_on according to the reference voltage Vref generated based on the screen brightness data Bdata. For example, the timing controller 350 may be configured to generate cathode-on voltage data Cdata_on according to the reference voltage data Vdata generated based on the screen brightness data Bdata. For example, the timing controller 350 may be configured to vary (or adjust) the second cathode-on voltage Vce_on2 according to the red reference voltage Vref_R, the green reference voltage Vref_G, and the blue reference voltage Vref_B generated based on the screen brightness data Bdata. For example, the timing controller 350 may be configured to generate the cathode-on voltage data Cdata_on for generating the second cathode-on voltage Vce_on2 based on the red reference voltage data, the green reference voltage data, and the blue reference voltage data corresponding to the screen brightness data Bdata.

Referring to FIGS. 12 and 13, the timing controller 350 according to an embodiment of the present disclosure may be configured to generate a cathode voltage control signal CVCS for sequentially supplying the cathode voltage Vce to a plurality of second electrodes CE2 (see FIG. 7) extending in a row direction of a display panel 100 and spaced apart in a column direction based on a timing synchronization signal. The cathode voltage control signal CVCS may include a plurality of cathode clock signals and a cathode voltage start signal. The cathode voltage control signal CVCS may be supplied to the pixel driving circuit PD.

In the display apparatus 1000 according to an embodiment of the present disclosure, a power management integrated circuit 370 may be configured to generate (or output) or vary (or adjust) a reference voltage Vref based on reference voltage data Vdata provided from a timing controller 350.

According to an embodiment of the present disclosure, the power management integrated circuit 370 may be configured to generate (or output) or vary (or adjust) a red reference voltage Vref_R based on red reference voltage data of the reference voltage data Vdata, to generate or output or vary or regulate a green reference voltage Vref_G based on green reference voltage data of the reference voltage data Vdata, and to generate or output or vary or regulate a blue reference voltage Vref_B based on blue reference voltage data of the reference voltage data Vdata.

The red reference voltage Vref_R may be commonly applied to a plurality of red micro-drivers (μDriver) (see FIG. 4) configured in the pixel driving circuit PD so as to be electrically connected to the red light emitting device. For example, the red reference voltage Vref_R may be commonly applied to a gate electrode of a driving transistor TDR configured in each of the plurality of red micro-drivers (μDriver). For example, the red micro-drivers (μDriver) may be a red sub-drivers (μDriver).

The green reference voltage Vref_G may be commonly applied to a plurality of green micro-drivers (μDriver) (see FIG. 4) configured in the pixel driving circuit PD so as to be electrically connected to the green light emitting device. For example, the green reference voltage Vref_G may be commonly applied to a gate electrode of a driving transistor TDR configured in each of the plurality of green micro-drivers (μDriver). For example, the green micro-drivers (μDriver) may be a green sub-drivers (μDriver).

The blue reference voltage Vref_B may be commonly applied to a plurality of blue micro-drivers (μDriver) (see FIG. 4) configured in the pixel driving circuit PD so as to be electrically connected to the blue light emitting device. For example, the blue reference voltage Vref_B may be commonly applied to a gate electrode of a driving transistor TDR configured in each of the plurality of blue micro-drivers (μDriver). For example, the blue micro-drivers (μDriver) may be a blue sub-drivers (μDriver).

The power management integrated circuit 370 according to an embodiment of the present disclosure may be configured to generate or vary (or adjust) the cathode-off voltage Vce_off based on the cathode-off voltage data Cdata_off provided from the timing controller 350. For example, the power management integrated circuit 370 may be configured to generate the cathode-off voltage Vce_off having a voltage level between the first cathode-off voltage Vce_off1 and the second cathode-off voltage Vce_off2 based on the cathode-off voltage data Cdata_off.

The power management integrated circuit 370 according to an embodiment of the present disclosure may be configured to generate or vary (or adjust) the cathode-on voltage Vce_on based on the cathode-on voltage data Cdata_on provided from the timing controller 350. For example, the power management integrated circuit 370 may be configured to generate the cathode-on voltage Vce_on having a voltage level between the first cathode-on voltage Vce_on1 and the second cathode-on voltage Vce_on2 based on the cathode-on voltage data Cdata_on.

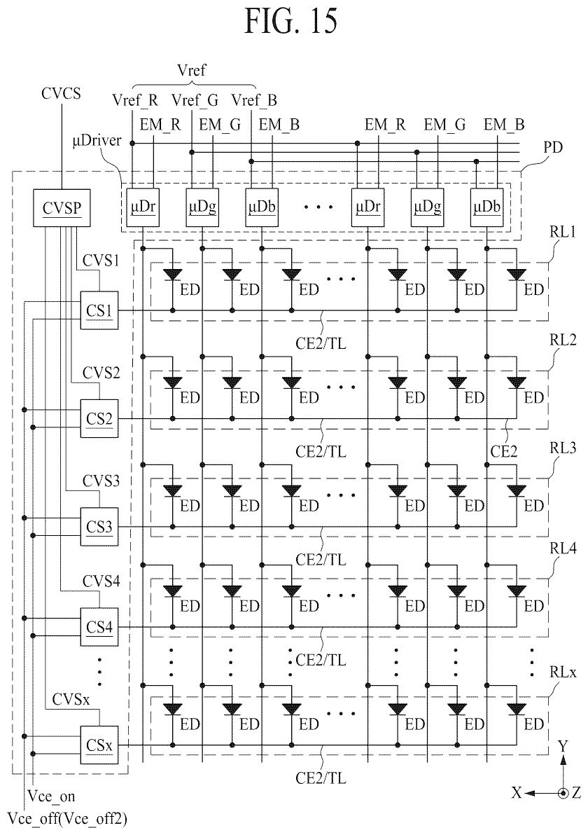

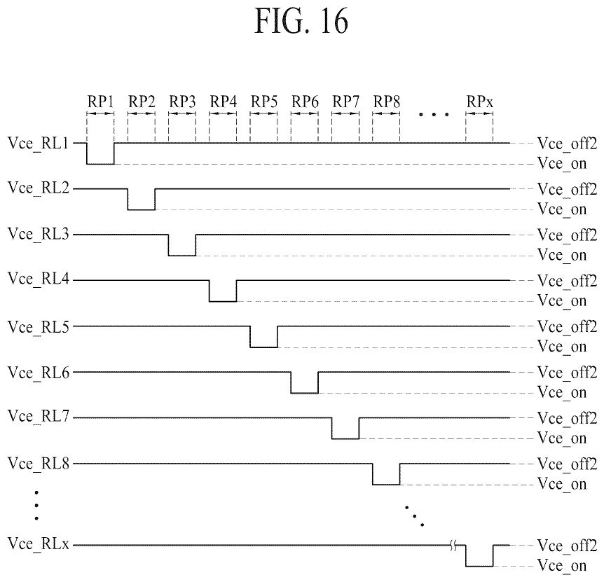

FIG. 15 illustrates a pixel driving circuit and a light emitting device in a display apparatus according to an embodiment of the present disclosure. FIG. 16 is a waveform diagram illustrating a cathode voltage applied to a plurality of second electrodes illustrated in FIG. 15 according to an embodiment of the present disclosure.

Referring to FIGS. 13, 15, and 16, in a display apparatus according to an embodiment of the present disclosure, a pixel driving circuit PD may include a plurality of micro-drivers (or sub-drivers) (μDriver), a cathode voltage selection signal generating part CVSP, and a plurality of cathode voltage supply circuits CS1 to CSx.

Each of the plurality of micro-drivers (μDriver) may be connected to a plurality of light emitting devices ED. For example, each of the plurality of micro-drivers (μDriver) may be commonly connected to the plurality of light emitting devices ED disposed along a column direction. For example, each of the plurality of micro-drivers (μDriver) may be commonly connected to 8 light emitting devices ED disposed along the column direction, but embodiments of the present disclosure are not limited thereto.

According to an embodiment of the present disclosure, the plurality of micro-drivers (μDriver) may include a plurality of red micro-drivers μDr, a plurality of green micro-drivers μDg, and a plurality of blue micro-drivers μDb.

Each of the plurality of red micro-drivers μDr may be commonly connected to a plurality of red light emitting devices ED disposed along the column direction. For example, each of the plurality of red micro-drivers μDr may be commonly connected to a first electrode (or an anode terminal) of 8 red light emitting devices ED disposed along the column direction, but embodiments of the present disclosure are not limited thereto. Each of the plurality of red micro-drivers μDr may be configured to sequentially emit light from the plurality of red light emitting devices ED based on a red reference voltage Vref_R provided from a power management integrated circuit 370 and a red emission signal EM_R provided from a driving circuit 311 (see FIG. 2). For example, each of the plurality of red micro-drivers μDr may be a circuit configured inside each of the plurality of micro-drivers (μDriver), and may be a red sub-driver, a red sub-pixel driving circuit, a red sub-pixel driving cell, or a red sub-pixel driver cell, but embodiments of the present disclosure are not limited thereto.

Each of the plurality of green micro-drivers μDg may be commonly connected to a plurality of green light emitting devices ED disposed along the column direction. For example, each of the plurality of green micro-drivers μDg may be commonly connected to a first electrode (or an anode terminal) of 8 green light emitting devices ED disposed along the column direction, but embodiments of the present disclosure are not limited thereto. Each of the plurality of green micro-drivers μDg may be configured to sequentially emit light from the plurality of green light emitting devices ED based on a green reference voltage Vref_G provided from the power management integrated circuit 370 and a green emission signal EM_G provided from the driving circuit 311 (see FIG. 2). For example, each of the plurality of green micro-drivers μDg may be a circuit configured inside each of the plurality of micro-drivers (μDriver), and may be a green sub-driver, a green sub-pixel driving circuit, a green sub-pixel driving cell, or a green sub-pixel driver cell, but embodiments of the present disclosure are not limited thereto.

Each of the plurality of blue micro-drivers μDb may be commonly connected to a plurality of blue light emitting devices ED disposed along the column direction. For example, each of the plurality of blue micro-drivers μDb may be commonly connected to a first electrode (or an anode terminal) of 8 blue light emitting devices ED disposed along the column direction, but embodiments of the present disclosure are not limited thereto. Each of the plurality of blue micro-drivers μDb may be configured to sequentially emit light from the plurality of blue light emitting devices ED based on a blue reference voltage Vref_B provided from the power management integrated circuit 370 and a blue emission signal EM_B provided from the driving circuit 311 (see FIG. 2). For example, each of the plurality of blue micro-drivers μDb may be a circuit configured inside each of the plurality of micro-drivers (μDriver), and may be a blue sub-driver, a blue sub-pixel driving circuit, a blue sub-pixel driving cell, or a blue sub-pixel driver cell, but embodiments of the present disclosure are not limited thereto.

The cathode voltage selection signal generating part CVSP may be configured to sequentially output a plurality of cathode voltage selection signals CVS1 to CVSx according to the cathode voltage control signal CVCS provided from the timing controller 350. For example, each of the plurality of cathode voltage selection signals CVS1 to CVSx may have a first logic period (or a high period) and a second logic period (or a low period) different from the first logic period. For example, the cathode voltage selection signal generating part CVSP may be a circuit configured inside the pixel driving circuit PD, but embodiments of the present disclosure are not limited thereto.

The second logic period of each of the plurality of cathode voltage selection signals CVS1 to CVSx may have a pulse width (or signal width) corresponding to one column driving period (or one horizontal period) RP1 to RP8 that causes a plurality of light emitting devices ED configured in one column (or one horizontal line) to emit light. Accordingly, the second logic period of each of the plurality of cathode voltage selection signals CVS1 to CVSx may be sequentially shifted in units of the one column driving period (or one horizontal period).

The cathode voltage selection signal generating part CVSP according to an embodiment of the present disclosure may be configured as a shift register that sequentially shifts the second logic period of the cathode voltage selection signal by the one column driving period (or one horizontal period) according to the cathode voltage control signal CVCS, but embodiments of the present disclosure are not limited thereto.

Each of the plurality of cathode voltage supply circuits CS1 to CSx may be configured to receive the cathode voltage control signal CVCS provided from the cathode voltage selection signal generating part CVSP and to receive the cathode-on voltage Vce_on and the cathode-on voltage Vce_off provided from the power management integrated circuit 370. Each of the plurality of cathode voltage supply circuits CS1 to CSx may be individually connected to a plurality of second electrodes CE2 (see FIG. 7) extending in the row direction of the display panel 100 and spaced apart from each other in the column direction. For example, each of the plurality of cathode voltage supply circuits CS1 to CSx may be individually connected to a corresponding second electrode CE2 configured in each of the plurality of columns (or horizontal lines) RL1 to RLx through a signal line TL.

Each of the plurality of cathode voltage supply circuits CS1 to CSx may be configured to apply any one of the cathode-on voltage Vce_on and the cathode-off voltage Vce_off to the corresponding second electrode CE2 among the plurality of second electrodes CE2 based on the cathode voltage control signal CVCS. For example, each of the plurality of cathode voltage supply circuits CS1 to CSx may be configured to apply the cathode-off voltage Vce_off to the corresponding second electrode CE2 among the plurality of second electrodes CE2 by the first logic period of the cathode voltage selection signals CVS1 to CVSx, and to apply the cathode-on voltage Vce_on to the corresponding second electrode CE2 among the plurality of second electrodes CE2 by the second logic period of the cathode voltage selection signals CVS1 to CVSx.

According to an embodiment of the present disclosure, each of the plurality of cathode voltage supply circuits CS1 to CSx may sequentially apply the cathode-on voltage Vce_on to the second electrodes CE2 configured in each of the plurality of columns (or horizontal lines) RL1 to RLx by the second logic period of the cathode voltage selection signals CVS1 to CVSx. Accordingly, the plurality of light emitting devices ED configured in each of the plurality of columns (or horizontal lines) RL1 to RLx may sequentially emit light by the cathode-on voltage Vce_on applied to the second electrodes CE2 in units of columns (or horizontal lines) RL1 to RLx.

According to an embodiment of the present disclosure, each of the plurality of cathode voltage supply circuits CS1 to CSx may sequentially apply the cathode-off voltage Vce_off to the second electrodes CE2 configured in each of the plurality of columns (or horizontal lines) RL1 to RLx by the first logic period of the cathode voltage selection signals CVS1 to CVSx. Accordingly, the light emission of each of the plurality of light emitting devices ED configured in each of the plurality of columns (or horizontal lines) RL1 to RLx may be sequentially turned off or switched off by the cathode-off voltage Vce_off in units of columns (or horizontal lines) RL1 to RLx.

According to an embodiment of the present disclosure, the cathode-off voltage Vce_off sequentially applied to the second electrode CE2 configured in each of the plurality of rows (or horizontal lines) RL1 to RLx may have a voltage level between the first cathode-off voltage Vce_off1 and the second cathode-off voltage Vce_off2 described above with reference to FIG. 12. For example, the cathode-off voltage Vce_off may have the second cathode-off voltage Vce_off2. Accordingly, the voltage swing width (or voltage transition width) between the cathode-on voltage Vce_on and the cathode-off voltage Vce_off may be reduced, and thus, power consumption due to voltage switching (or voltage transition) may be reduced.

As described above, in the display apparatus according to an embodiment of the present disclosure, the power consumption may be reduced by varying (or adjusting) the cathode-off voltage Vce_off applied to the second electrode CE2.

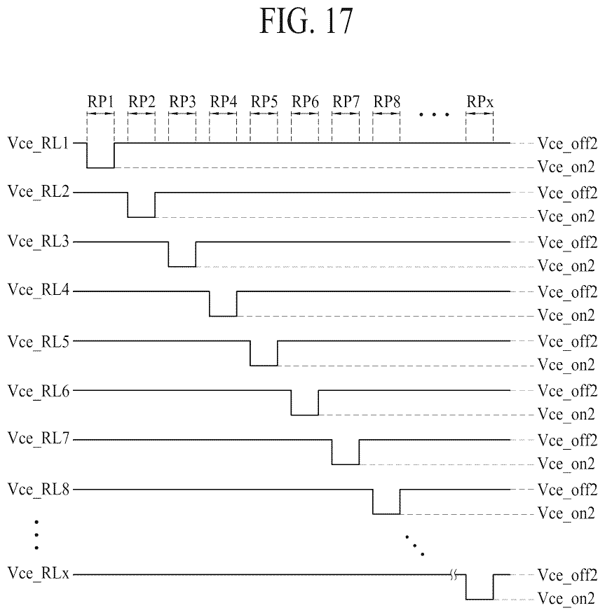

FIG. 17 is a waveform diagram illustrating a cathode voltage applied to a plurality of second electrodes illustrated in FIG. 15. FIG. 17 illustrates an embodiment implemented by changing a cathode-on voltage described above with reference to FIGS. 15 and 16. Therefore, in the following description, repetitive descriptions to the other elements other than a cathode-on voltage and relevant elements are omitted. The description with reference above to FIGS. 15 and 16 may be included in the description of FIG. 17.

Referring to FIGS. 15 and 17, each of the plurality of cathode voltage supply circuits CS1 to CSx according to another embodiment of the present disclosure may sequentially apply the cathode-on voltage Vce_on to the second electrode CE2 configured in each of a plurality of columns (or horizontal lines) RL1 to RLx by the second logic period of the cathode voltage selection signal CVS1 to CVSx. Accordingly, the plurality of light emitting devices ED configured in each of the plurality of columns (or horizontal lines) RL1 to RLx may sequentially emit light by the cathode-on voltage Vce_on applied to the second electrode CE2 in units of columns (or horizontal lines) RL1 to RLx.

According to another embodiment of the present disclosure, the cathode-on voltage Vce_on sequentially applied to the second electrode CE2 configured in each of the plurality of rows (or horizontal lines) RL1 to RLx may have a voltage level between the first cathode-on voltage Vce_on1 and the second cathode-on voltage Vce_on2 described above with reference to FIG. 12. For example, the cathode-on voltage Vce_on may have the second cathode-on voltage Vce_on2. Accordingly, the brightness of the light emitting device ED may be increased by the second cathode-on voltage Vce_on2.

Each of the plurality of cathode voltage supply circuits CS1 to CSx according to another embodiment of the present disclosure may sequentially apply the cathode-off voltage Vce_off to the second electrodes CE2 configured in each of the plurality of columns (or horizontal lines) RL1 to RLx by the first logic period of the cathode voltage selection signals CVS1 to CVSx. Accordingly, the light emission of each of the plurality of light emitting devices ED configured in each of the plurality of columns (or horizontal lines) RL1 to RLx may be sequentially turned off or switched off by the cathode-off voltage Vce_off in units of columns (or horizontal lines) RL1 to RLx.

According to an embodiment of the present disclosure, the cathode-off voltage Vce_off sequentially applied to the second electrode CE2 configured in each of the plurality of rows (or horizontal lines) RL1 to RLx may have a voltage level between the first cathode-off voltage Vce_off1 and the second cathode-off voltage Vce_off2 described above with reference to FIG. 12. For example, the cathode-off voltage Vce_off may have the second cathode-off voltage Vce_off2. Accordingly, the voltage swing width (or voltage transition width) between the cathode-on voltage Vce_on and the cathode-off voltage Vce_off may be reduced, and thus, the power consumption according to voltage switching (or voltage transition) may be reduced. Accordingly, the display apparatus according to an embodiment of the present disclosure may reduce power consumption by varying (or adjusting) the cathode-off voltage Vce_off applied to the second electrode CE2.

As described above, in the display apparatus according to another embodiment of the present disclosure, the power consumption may be reduced by varying or (or adjusting) the cathode-off voltage Vce_off applied to the second electrode CE2, and brightness due to light emission of the light emitting device ED may be increased by varying (or adjusting) the cathode-on voltage Vce_on.

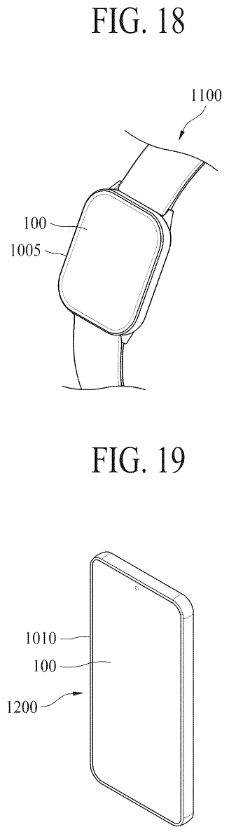

FIGS. 18 to 21 are diagrams illustrating an apparatus to which a display apparatus according to embodiments of the present disclosure is applied.

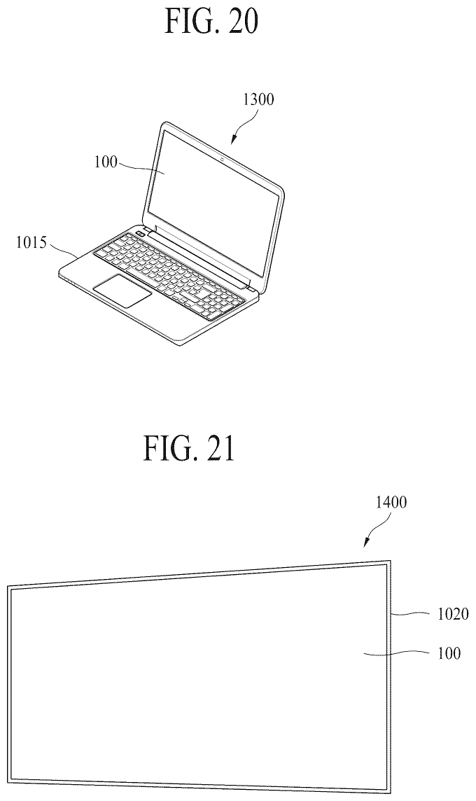

Referring to FIGS. 18 to 21, the display apparatus according to an embodiment of the present disclosure may be applied to or included in various apparatuses or electronic apparatuses. For example, the various electronic apparatuses may include a wearable device 1100 illustrated in FIG. 18, a mobile device 1200 illustrated in FIG. 19, a notebook 1300 illustrated in FIG. 20, and a monitor or TV 1400 illustrated in FIG. 21, but embodiments of the present disclosure are not limited thereto.

Each of the wearable device 1100, the mobile device 1200, the notebook 1300, and the monitor or TV 1400 may respectively include a case part 1005, 1010, 1015, and 1020, and the display panel 100 and the display apparatus 1000 according to the above-described embodiments of the present disclosure. Therefore, descriptions to the display panel 100 and the display apparatus 1000 are omitted. The description with reference above to FIGS. 1 to 17 may be included in the description of FIGS. 18 to 21.

For example, the display apparatus according to an embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a PMP (a portable multimedia player), a PDA (a personal digital assistant), an MP3 (MPEG Audio Layer 3) player, a mobile medical device, a desktop personal computer, a laptop personal computer, a netbook computer, a workstation, a navigation, a vehicle display apparatus, a theater display apparatus, a television, a wallpaper device, a signage device, a game device, a notebook, a monitor, a camera, a camcorder, or a home appliances, or the like.

It will be apparent to those skilled in the art that various modifications and variations may be made in the present disclosure without departing from the spirit or scope of the disclosures. Thus, it is intended that the present disclosure covers the modifications and variations of this disclosure provided that within the scope of the claims and their equivalents.

What is claimed is:

1. A display apparatus comprising:
a substrate including a display area and a non-display area;
a pixel driving circuit at the display area on the substrate;
an insulating layer over the pixel driving circuit;
a plurality of light emitting devices spaced apart from each other over the insulating layer, the plurality of light emitting devices electrically connected to the pixel driving circuit; and
a plurality of common cathode electrodes electrically connected to the plurality of light emitting devices, the plurality of common cathode electrodes configured to receive a cathode voltage,
wherein the cathode voltage has a cathode-on voltage or a cathode-off voltage and the cathode-off voltage is variable.

2. The display apparatus of claim 1, wherein the plurality of common cathode electrodes extend along a row direction and are spaced apart from each other along a column direction, and the cathode-on voltage is sequentially applied to the plurality of common cathode electrodes.

3. The display apparatus of claim 1, wherein the cathode-off voltage is variable based on a screen brightness set by a user.

4. The display apparatus of claim 3, further comprising:
a touch panel configured to sense the screen brightness in response to a user's touch.

5. The display apparatus of claim 1, wherein:
a threshold voltage of a light emitting device from the plurality of light emitting devices has a voltage level that is higher than a voltage difference between an anode voltage of the light emitting device and the cathode-off voltage, and lower than a voltage difference between the anode voltage of the light emitting device and the cathode-on voltage, and
the cathode-off voltage has a voltage level between the anode voltage of the light emitting device and the threshold voltage of the light emitting device.

6. The display apparatus of claim 1, wherein:
the pixel driving circuit includes a plurality of sub-drivers electrically connected to each of the plurality of light emitting devices, and
each of the plurality of sub-drivers is configured to apply a driving current to a corresponding light emitting device of the plurality of light emitting devices based on a reference voltage and an emission signal corresponding to pixel data.

7. The display apparatus of claim 6, wherein:
the reference voltage is variable based on a screen brightness set by a user, and
the cathode-off voltage is variable based on the reference voltage, and/or
the cathode-on voltage is variable based on the reference voltage.

8. The display apparatus of claim 7, further comprising:
a timing controller configured to generate reference voltage data, cathode-on voltage data, and cathode-off voltage data based on the screen brightness set by the user; and
a power management integrated circuit configured to output the reference voltage based on the reference voltage data, to output the cathode-on voltage based on the cathode-on voltage data, and to output the cathode-off voltage based on the cathode-off voltage data.

9. The display apparatus of claim 8, wherein the timing controller is configured to:
generate the reference voltage data corresponding to the screen brightness set by the user using a look-up table stored in memory, and
generate the cathode-off voltage data corresponding to the screen brightness set by the user using the look-up table.

10. The display apparatus of claim 8, wherein:
the timing controller is configured to output a cathode voltage control signal, and
the pixel driving circuit further comprises:
a cathode voltage selection signal generating part configured to sequentially output a plurality of cathode voltage selection signals based on the cathode voltage control signal; and
a plurality of cathode voltage supply circuits configured to sequentially apply the cathode-on voltage or the cathode-off voltage to the plurality of common cathode electrodes based on the plurality of cathode voltage selection signals.

11. The display apparatus of claim 8, wherein:
the plurality of light emitting devices comprise a plurality of red light emitting devices, a plurality of green light emitting devices, and a plurality of blue light emitting devices,
the plurality of sub-drivers comprise:
a plurality of red sub-drivers electrically connected to the plurality of red light emitting devices, the plurality of red sub-drivers configured to apply a driving current to the plurality of red light emitting devices based on a red reference voltage and a red emission signal;
a plurality of green sub-drivers electrically connected to the plurality of green light emitting devices, the plurality of green sub-drivers configured to apply a driving current to the plurality of green light emitting devices based on a green reference voltage and a green emission signal; and
a plurality of blue sub-drivers electrically connected to the plurality of blue light emitting devices, the plurality of blue sub-drivers configured to apply a driving current to the plurality of blue light emitting devices based on a blue reference voltage and a blue emission signal, and
the red reference voltage, the green reference voltage, and the blue reference voltage are different from each other based on the screen brightness set by the user.

12. The display apparatus of claim 6, wherein a brightness of the plurality of light emitting devices comprises:
a first brightness region including a minimum brightness;
a third brightness region including a maximum brightness; and
a second brightness region between the first brightness region and the third brightness region, and
wherein the reference voltage is variable in each of the first brightness region and the third brightness region.

13. The display apparatus of claim 12, wherein the plurality of light emitting devices include a red light emitting device, a green light emitting device, and a blue light emitting device, and the first brightness region, the second brightness region, and the third brightness region of each of the red light emitting device, the green light emitting device, and the blue light emitting device are different from each other.

14. The display apparatus of claim 12, wherein the plurality of light emitting devices are configured to:
emit light by a pulse amplitude modulation method based on the reference voltage and the emission signal in each of the first brightness region and the third brightness region, and
emit light by a pulse width modulation method based on the reference voltage and the emission signal in the second brightness region.

15. The display apparatus of claim 12, wherein the cathode-off voltage is variable based on the reference voltage or each of the cathode-off voltage and the cathode-on voltage is variable based on the reference voltage.

16. The display apparatus of claim 1, further comprising:
a plurality of banks at the insulating layer;
a plurality of connection electrodes at each of the plurality of banks, the plurality of connection electrodes electrically connected to the pixel driving circuit; and
a plurality of bonding pads at each of the plurality of connection electrodes,
wherein each of the plurality of light emitting devices comprises:
a first electrode electrically connected to a corresponding bonding pad of the plurality of bonding pads; and
a second electrode electrically connected to a corresponding common cathode electrode of the plurality of common cathode electrodes.

17. The display apparatus of claim 16, further comprising:
an optical layer over the insulating layer, the optical layer surrounding lateral surfaces of each of the plurality of light emitting devices and lateral surfaces of each of the plurality of banks.

18. The display apparatus of claim 17, wherein the optical layer comprises:
a first optical layer surrounding side portions of the plurality of light emitting devices and the plurality of banks between the plurality of common cathode electrodes and the insulating layer; and
a second optical layer surrounding side portions of the first optical layer.

19. The display apparatus of claim 18, wherein the optical layer further comprises a third optical layer disposed over the plurality of common cathode electrodes and overlaps the plurality of light emitting devices and the first optical layer.

20. The display apparatus of claim 16, further comprising:
a cover layer over the plurality of common cathode electrodes;
a polarizing layer over the cover layer; and
a cover member over the polarizing layer.
